(19) United States
(12) Patent Application Publication
(10) Pub. No.: US 2026/0020277 A1
(43) Pub. Date: Jan. 15, 2026

(54) NITRIDE SEMICONDUCTOR DEVICE

(71) Applicant: ROHM CO., LTD., Kyoto-shi (JP)

(72) Inventor: Kenichi YOSHIMOCHI, Kyoto-shi (JP)

(73) Assignee: ROHM CO., LTD., Kyoto-shi (JP)

(21) Appl. No.: 19/336,569

(22) Filed: Sep. 23, 2025

Related U.S. Application Data
(63) Continuation of application No. PCT/JP2024/009572, filed on Mar. 12, 2024.

(30) Foreign Application Priority Data
Mar. 30, 2023 (JP) 2023-055059

(51) Int. Cl. H10D 30/47; H10D 62/10; H10D 62/824; H10D 64/00

(52) U.S. Cl. CPC H10D 30/475; H10D 62/102; H10D 64/112; H10D 62/824

(57) ABSTRACT

This nitride semiconductor device includes: a gate layer that is formed on an electron supply layer; a gate electrode that is formed on the gate layer; a passivation layer that covers the electron supply layer, the gate layer, and the gate electrode and has a first opening and a second opening that are separated in the X direction; and a field plate electrode that is formed on the passivation layer and is electrically connected to a source electrode. The field plate electrode includes a plate extension that extends to a region between the gate layer and a drain electrode in a plan view and opposes the electron supply layer with the passivation layer therebetween. An opening is formed in the plate extension of the field plate electrode.

### CROSS-REFERENCE TO RELATED APPLICATIONS

This application is a continuation of, and claims the benefit of priority from International Application No. PCT/JP2024/009572, filed on Mar. 12, 2024, which claims the benefit of priority from Japanese Patent Application No. 2023-055059, filed on Mar. 30, 2023, the entire contents of each are incorporated herein by reference.

### BACKGROUND

### 1. Field

The present disclosure relates to a nitride semiconductor device.

### 2. Description of Related Art

High-electron-mobility transistors (HEMTs) are now being commercialized. A HEMT is one type of field effect transistor (FET) that uses a group III semiconductor such as gallium nitride (GaN) (for example, refer to JP2017-73506A).

A nitride semiconductor device having such a structure includes, for example, an electron transit layer, an electron supply layer formed on the electron transit layer and having a larger band gap than the electron transit layer, a gate layer formed on the electron transit layer and including an acceptor impurity, a gate electrode formed on the gate layer, and a passivation layer covering the electron supply layer, the gate layer, and the gate electrode. The nitride semiconductor device further includes a field plate electrode integrated with a source electrode. The field plate electrode extends from the source electrode toward the drain electrode over the gate layer and the gate electrode.

### BRIEF DESCRIPTION OF THE DRAWINGS

FIG. 1 is a schematic plan view of an exemplary nitride semiconductor device in a first embodiment.

FIG. 2 is an enlarged schematic plan view of a portion of the nitride semiconductor device in dashed section A1 in FIG. 1 including a passivation layer and field plate electrodes.

FIG. 3 is a schematic cross-sectional view of the nitride semiconductor device taken along line F3-F3 in FIG. 2.

FIG. 4 is a schematic cross-sectional view of the nitride semiconductor device taken along line F4-F4 in FIG. 2.

FIG. 5 is an enlarged schematic plan view of dashed section A2 shown in FIG. 2.

FIG. 6 is an enlarged schematic plan view of dashed section A2 shown in FIG. 2 illustrating a state of a depletion layer to which drain-source voltage is applied.

FIG. 7 is an enlarged schematic plan view of a second embodiment of a nitride semiconductor device including field plate electrodes.

FIG. 8 is a schematic cross-sectional view of the nitride semiconductor device taken along line F8-F8 in FIG. 7.

FIG. 9 is an enlarged schematic plan view of a third embodiment of a nitride semiconductor device including field plate electrodes.

FIG. 10 is a schematic cross-sectional view of the nitride semiconductor device taken along line F10-F10 in FIG. 9.

FIG. 11 is an enlarged schematic plan view of a modified example of a nitride semiconductor device showing openings of a field plate electrode.

FIG. 12 is an enlarged schematic plan view of a modified example of a nitride semiconductor device showing openings of a field plate electrode.

FIG. 13 is an enlarged schematic plan view of a modified example of a nitride semiconductor device showing openings of a field plate electrode.

FIG. 14 is an enlarged schematic plan view of a modified example of a nitride semiconductor device showing openings of a field plate electrode.

FIG. 15 is an enlarged schematic plan view of a modified example of a nitride semiconductor device showing field plate electrodes.

FIG. 16 is an enlarged schematic plan view of a modified example of a nitride semiconductor device showing field plate electrodes.

FIG. 17 is an enlarged schematic plan view of a modified example of a nitride semiconductor device showing field plate electrodes.

FIG. 18 is an enlarged schematic plan view of a modified example of a nitride semiconductor device showing field plate electrodes.

FIG. 19 is an enlarged schematic plan view of a modified example of a nitride semiconductor device showing field plate electrodes.

FIG. 20 is an enlarged schematic plan view of a modified example of a nitride semiconductor device showing field plate electrodes.

FIG. 21 is an enlarged schematic plan view of a modified example of a nitride semiconductor device showing field plate electrodes.

FIG. 22 is an enlarged schematic plan view of a modified example of a nitride semiconductor device showing field plate electrodes.

FIG. 23 is an enlarged schematic plan view of a modified example of a nitride semiconductor device showing field plate electrodes.

FIG. 24 is an enlarged schematic plan view of a modified example of a nitride semiconductor device showing field plate electrodes.

FIG. 25 is a schematic cross-sectional view of the nitride semiconductor device taken along line F25-F25 in FIG. 24.

FIG. 26 is a schematic cross-sectional view of a modified example of a nitride semiconductor device.

FIG. 27 is a schematic cross-sectional view of a modified example of a nitride semiconductor device.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

In the following description, phrases such as “the dimensions (width, depth, length, distance) of component A is equal to the dimensions (width, depth, length, distance) of component B” and “the dimensions (width, depth, length, distance) of component A and the dimensions (width, depth, length, distance) of component B are equal to each other” mean that the absolute value of the difference between the dimensions (width, depth, length, distance) of component A and the dimensions (width, depth, length, distance) of component B is, for example, within 10% of the dimensions (width, depth, length, distance) of component A.

### First Embodiment

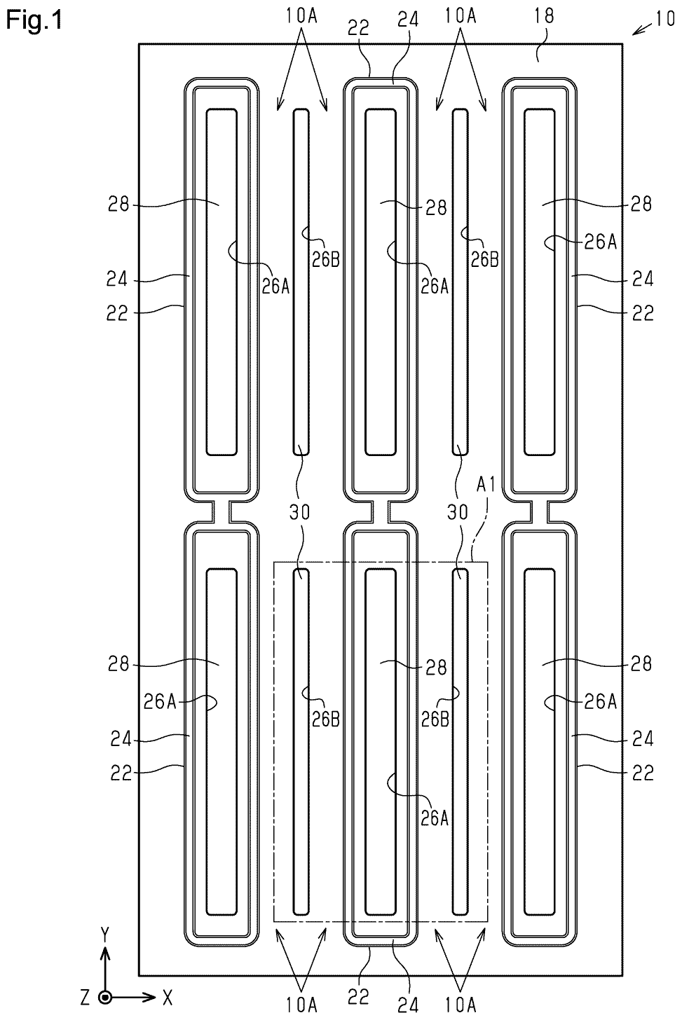

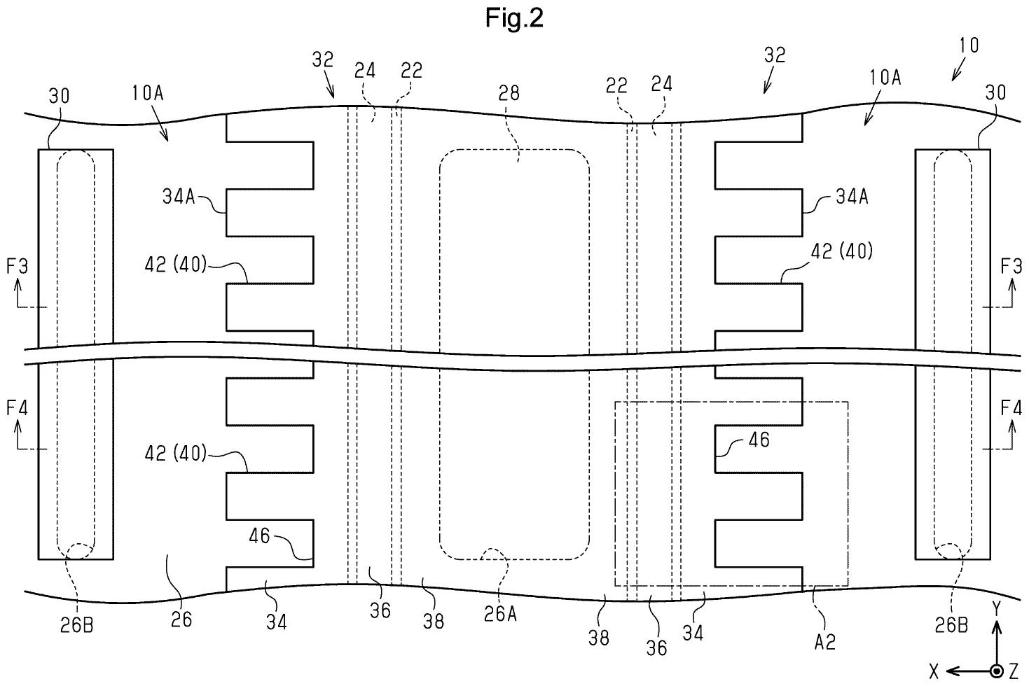

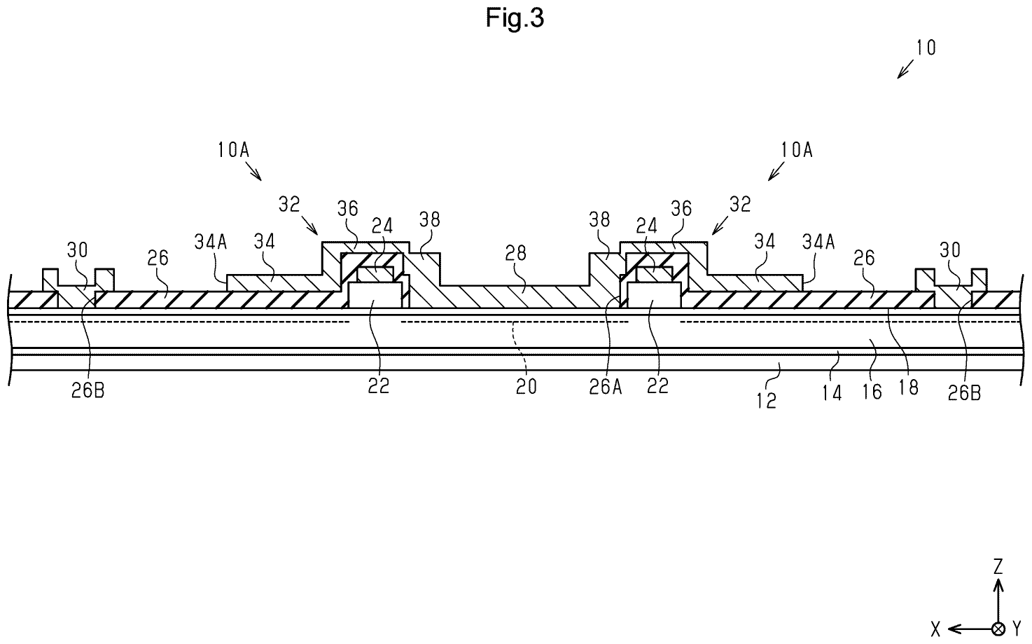

A first embodiment of a nitride semiconductor device 10 will now be described with reference to FIGS. 1 to 6. FIG. 1 schematically shows a planar structure of the nitride semiconductor device 10. FIG. 2 schematically shows a planar structure of the nitride semiconductor device 10 partially enlarged from that shown in FIG. 1. FIG. 3 schematically shows a cross-sectional structure of the nitride semiconductor device 10 taken along line F3-F3 in FIG. 2.

The nitride semiconductor device 10 is a high-electron-mobility transistor (HEMT) that uses a nitride semiconductor. The nitride semiconductor may include, for example, gallium nitride (GaN), aluminum nitride (AlN), and indium nitride (InN), and may be typically expressed as AlₓIn_{y}Ga_{1-x-y}, where 0≤x≤1, 0≤y≤1, and 0≤x+y≤1.

Unless otherwise specifically described, the term “plan view” used in the present disclosure refers to a view of an object (nitride semiconductor device 10 or its component) in a Z-direction when XYZ-axes shown in the drawings are orthogonal to each other.

### Schematic Cross-Sectional Structure of Nitride Semiconductor Device

As shown in FIG. 1, the nitride semiconductor device 10 includes multiple unit transistors 10A having an HEMT structure using a nitride semiconductor. The HEMT structure of a single unit transistor 10A will now be described with reference to FIG. 3. The description also applies to other unit transistors 10A.

As shown in FIG. 3, the unit transistor 10A (nitride semiconductor device 10) includes a semiconductor substrate 12, a buffer layer 14 formed on the semiconductor substrate 12, an electron transit layer 16 formed on the buffer layer 14, and an electron supply layer 18 formed on the electron transit layer 16.

The semiconductor substrate 12 may be formed of silicon (Si), silicon carbide (SIC), GaN, sapphire, or other substrate materials. In an example, the semiconductor substrate 12 may be a Si substrate. The semiconductor substrate 12 may have a thickness that is, for example, greater than or equal to 200 μm and less than or equal to 1500 μm.

The buffer layer 14 may be disposed between the semiconductor substrate 12 and the electron transit layer 16. In an example, the buffer layer 14 may be composed of any material that facilitates epitaxial growth of the electron transit layer 16. The buffer layer 14 may include one or more nitride semiconductor layers.

In an example, the buffer layer 14 may include at least one of an AlN layer, an aluminum gallium nitride (AlGaN) layer, and a graded AlGaN layer having different aluminum (Al) compositions. In an example, the buffer layer 14 may include a single AlN layer, a single AlGaN layer, a layer having an AlGaN/GaN superlattice structure, a layer having an AlN/AlGaN superlattice structure, or a layer having an AlN/GaN superlattice structure. To inhibit current leakage of the buffer layer 14, a portion of the buffer layer 14 may be doped with an impurity so that the buffer layer 14 becomes semi-insulating. In this case, the impurity is, for example, carbon (C) or iron (Fe). The concentration of the impurity may be, for example, greater than or equal to 4×10¹⁶ cm⁻³.

The electron transit layer 16 is composed of a nitride semiconductor. The electron transit layer 16 is, for example, a GaN layer. The electron transit layer 16 has a thickness that is, for example, greater than or equal to 0.5 μm and less than or equal to 2 μm. To inhibit current leakage of the electron transit layer 16, the electron transit layer 16 may be partially doped with an impurity so that the electron transit layer 16, excluding its surface region, becomes semi-insulating. In this case, the impurity is, for example, C. The peak concentration of the impurity in the electron transit layer 16 may be, for example, greater than or equal to 1×10¹⁹ cm⁻³.

The electron supply layer 18 is composed of a nitride semiconductor having a bandgap that is larger than that of the electron transit layer 16. The electron supply layer 18 may be, for example, an AlGaN layer. In this case, the bandgap becomes larger as the Al composition increases. Thus, the electron supply layer 18, which is an AlGaN layer, has a larger band gap than the electron transit layer 16, which is a GaN layer. In an example, the electron supply layer 18 is formed from AlₓGa₁₋ₓN, where 0.1<x<0.4, and more preferably, 0.2<x<0.3. The electron supply layer 18 has a thickness that is, for example, greater than or equal to 5 nm and less than or equal to 20 nm.

The electron transit layer 16 and the electron supply layer 18 are composed of nitride semiconductors having different lattice constants. Thus, the nitride semiconductor forming the electron transit layer 16 (e.g., GaN) and the nitride semiconductor forming the electron supply layer 18 (e.g., AlGaN) form a lattice-mismatching heterojunction. The energy level of the conduction band of the electron transit layer 16 in the vicinity of the heterojunction interface is lower than the Fermi level due to spontaneous polarization of the electron transit layer 16 and the electron supply layer 18 and piezoelectric polarization caused by stress applied to the electron supply layer 18 in the vicinity of the heterojunction interface. As a result, at a location close to the heterojunction interface between the electron transit layer 16 and the electron supply layer 18 (e.g., within range approximately a few nanometers from the interface), two-dimensional electron gas 20 (2DEG) spreads in the electron transit layer 16.

The unit transistor 10A (nitride semiconductor device 10) further includes a gate layer 22 formed on the electron supply layer 18, a gate electrode 24 formed on the gate layer 22, and a passivation layer 26. The passivation layer 26 is formed on the electron supply layer 18, the gate layer 22, and the gate electrode 24 and has a first opening 26A and a second opening 26B. The first opening 26A and the second opening 26B are separated from each other in the X-direction. The nitride semiconductor device 10 further includes a source electrode 28, which is in contact with the electron supply layer 18 through the first opening 26A, and a drain electrode 30, which is in contact with the electron supply layer 18 through the second opening 26B. The X-direction corresponds to a “first direction.”

The gate layer 22 is located between the first opening 26A and the second opening 26B of the passivation layer 26 and is separated from each of the first opening 26A and the second opening 26B. The gate layer 22 is located closer to the first opening 26A than to the second opening 26B.

The gate layer 22 has a smaller band gap than the electron supply layer 18 and is composed of a nitride semiconductor containing an acceptor impurity. The gate layer 22 may be formed of any material having a band gap that is smaller than that of the electron supply layer 18, which is, for example, an AlGaN layer. In an example, the gate layer 22 is a GaN layer (p-type GaN layer) doped with an acceptor impurity. The acceptor impurity may contain at least one of zinc (Zn), magnesium (Mg), and carbon (C). The maximum concentration of the acceptor impurity in the gate layer 22 is, for example, greater than or equal to 1×10¹⁸ cm⁻³ and less than or equal to 1×10²⁰ cm⁻³.

As described above, the acceptor impurity included in the gate layer 22 increases the energy levels of the electron transit layer 16 and the electron supply layer 18. As a result, in a region immediately below the gate layer 22, the energy level of the conduction band of the electron transit layer 16 in the vicinity of the heterojunction interface between the electron transit layer 16 and the electron supply layer 18 is substantially equal to or greater than the Fermi level. Therefore, when no voltage is applied to the gate electrode 24, that is, in the zero bias state, the 2DEG 20 is not formed in the electron transit layer 16 in the region immediately below the gate layer 22. On the other hand, in a region other than the region immediately below the gate layer 22, the 2DEG 20 is formed in the electron transit layer 16.

In this manner, the gate layer 22, which is doped with the acceptor impurity, depletes the 2DEG 20 at the region immediately below the gate layer 22. This results in the transistor being normally off. The application of an appropriate on-voltage to the gate electrode 24 will form a channel with the 2DEG 20 in the electron transit layer 16 at the region immediately below the gate electrode 24 and electrically connect the source and drain.

The gate electrode 24 is composed of one or more metal layers. In one example, the gate electrode 24 is a titanium nitride (TiN) layer. Alternatively, the gate electrode 24 may be formed by a first metal layer of a material containing Ti and a second metal layer formed from a material containing TiN. The gate electrode 24 and the gate layer 22 may form a Schottky junction. The gate electrode 24 may be formed in a region smaller than the gate layer 22 in plan view. The gate electrode 24 has a thickness that is, for example, greater than or equal to 50 nm and less than or equal to 200 nm.

The passivation layer 26 is formed on the electron supply layer 18. The passivation layer 26 covers the electron supply layer 18, the gate layer 22, and the gate electrode 24. The passivation layer 26 may be formed from a material containing one of, for example, silicon nitride (SiN), silicon dioxide (SiO₂), silicon oxynitride (SiON), alumina (Al₂O₃), AlN, and aluminum oxynitride (AlON). The passivation layer 26 is greater in thickness than the electron supply layer 18. The thickness of the passivation layer 26 is, for example, greater than or equal to 300 nm and less than or equal to 1000 nm. The thickness of the passivation layer 26 may be changed in any manner.

The source electrode 28 and the drain electrode 30 are located at opposite sides of the gate layer 22 on the upper surface of the electron supply layer 18. The source electrode 28 and the drain electrode 30 may be formed of one or more metal layers. For example, the source electrode 28 and the drain electrode 30 may be formed of a combination of two or more metal layers selected from a Ti layer, a TiN layer, an Al layer, an AlSiCu layer, and an AlCu layer. At least a portion of the source electrode 28 fills the first opening 26A. This allows the source electrode 28 to be in ohmic contact with the 2DEG 20, which is located immediately below the electron supply layer 18, through the first opening 26A. Also, at least a portion of the drain electrode 30 fills the second openings 26B. This allows the drain electrode 30 to be in ohmic contact with the 2DEG 20, which is located immediately below the electron supply layer 18, through the second opening 26B.

The unit transistor 10A (nitride semiconductor device 10) further includes a field plate electrode 32 electrically connected to the source electrode 28. In the first embodiment, the field plate electrode 32 is formed integrally with the source electrode 28. The field plate electrode 32 mitigates electric field concentration at the vicinity of the end of the gate electrode 24 and the vicinity of the end of the gate layer 22 when a drain voltage is applied to the drain electrode 30 in the zero bias state, in which no gate input voltage is applied to the gate electrode 24. The structure of the field plate electrode 32 will be described later in detail.

### Schematic Planar Structure of Nitride Semiconductor Device

An exemplary schematic planar structure of the nitride semiconductor device 10 will now be described with reference to the schematic planar structure of the nitride semiconductor device 10 shown in FIG. 1 will now be described. To facilitate the understanding of the planar structure and the arrangement of the gate layer 22, the gate electrode 24, the source electrode 28, and the drain electrode 30, FIG. 1 does not show the passivation layer 26 and the field plate electrode 32. FIG. 1 shows the planar structure of a contact portion of each of the source electrode 28 and the drain electrode 30 that is in contact with the electron supply layer 18.

As shown in FIG. 1, the nitride semiconductor device 10 includes multiple source electrodes 28 arranged on the electron supply layer 18 in the X-direction and the Y-direction in plan view. In the example shown in FIG. 1, a total of six source electrodes 28 are arranged in three columns in the X-direction and two rows in the Y-direction. Each source electrode 28 has the form of a strip and extends in the Y-direction in plan view.

The nitride semiconductor device 10 includes multiple drain electrodes 30 arranged on the electron supply layer 18 in the X-direction and the Y-direction in plan view. In the example shown in FIG. 1, a total of four drain electrodes 30 are separated from each other and arranged in two columns in the X-direction and two rows in the Y-direction. Each drain electrode 30 has the form of a strip and extends in the Y-direction in plan view. The drain electrodes 30 and the source electrodes 28 are alternately arranged in the X-direction. In this case, for example, the source electrodes 28 is located at opposite ends in the X-direction.

The nitride semiconductor device 10 further includes multiple pieces of the gate layer 22 and the gate electrodes 24 arranged on the electron supply layer 18 in the X-direction and the Y-direction. In the example shown in FIG. 1, a total of six pieces of the gate layer 22 and six gate electrodes 24 are arranged in three columns in the X-direction and two rows in the Y-direction. The gate layer 22 and the gate electrode 24 extend in the Y-direction and surround the source electrode 28 in plan view. That is, the gate layer 22 and the gate electrode 24 are annular.

The term “annular” as used in the present disclosure is not limited to a structure that forms a continuous shape with no ends, that is, a loop, but may refer to, for example, a structure with a slit (gap) such as a C-shaped structure. Such “annular” shapes include an ellipse and any other shapes including round corners or corners having a predetermined angle such as a right angle.

### Schematic Configuration of Field Plate Electrode

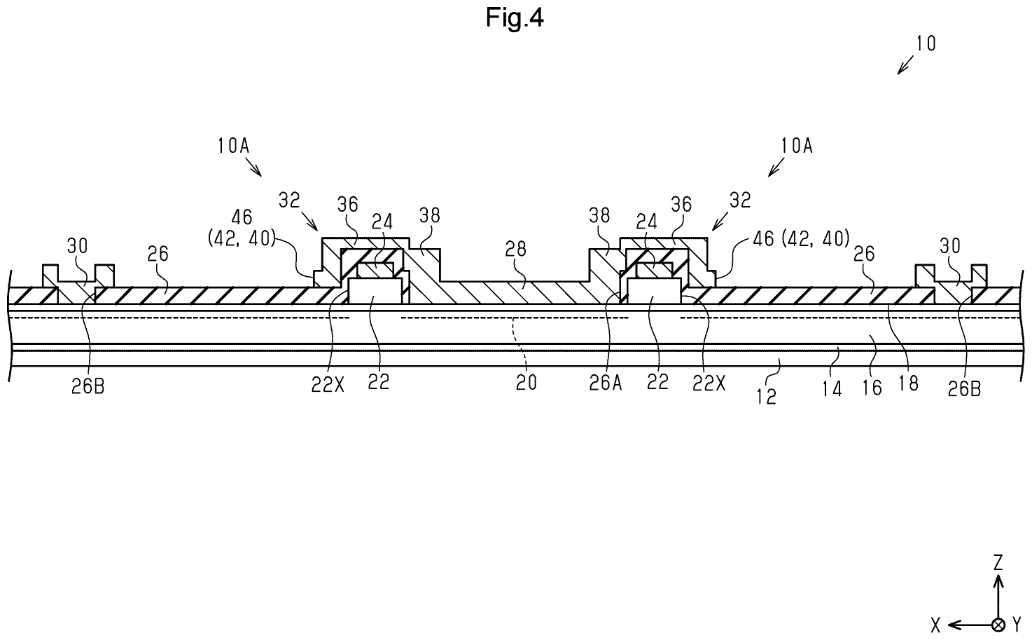

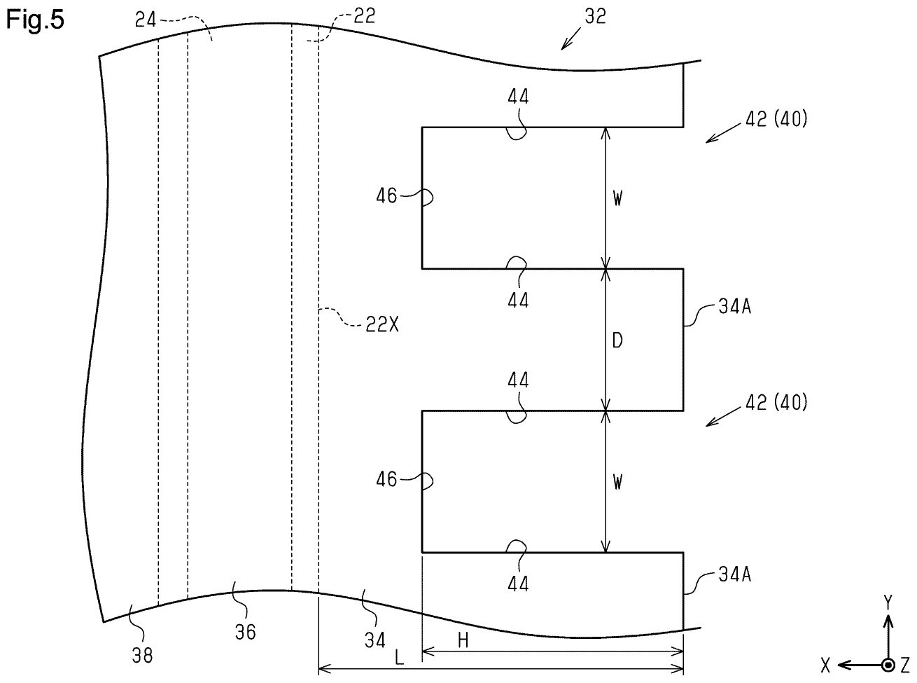

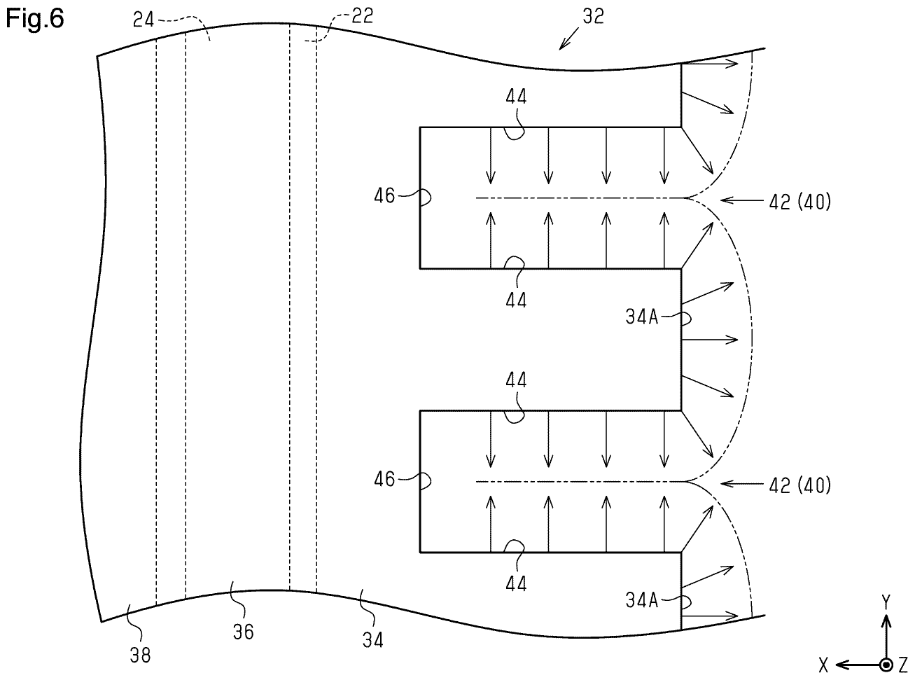

An exemplary schematic configuration of the field plate electrode 32 will now be described with reference to FIGS. 2 to 6. FIG. 2 schematically shows a planar structure of the nitride semiconductor device 10 in dashed section A1 shown in FIG. 1. FIG. 2 is an enlarged view of FIG. 1 in which the passivation layer 26 and the field plate electrode 32 are added. FIG. 2 does not show a portion of FIG. 1 in the Y-direction. FIG. 4 schematically shows a cross-sectional structure of the nitride semiconductor device 10 taken along line F4-F4 in FIG. 2. FIGS. 5 and 6 each schematically show a planar structure in dashed section A2 shown in FIG. 2.

As shown in FIG. 2, the field plate electrode 32 is arranged in the X-direction between two drain electrodes 30, which are separated from each other in the X-direction. The field plate electrode 32 is rectangular in plan view. The field plate electrode 32 is located at opposite sides of the source electrode 28 in the X-direction. The field plate electrode 32 extends in a region between the gate layer 22 and the drain electrode 30 in plan view.

As shown in FIG. 3, the field plate electrode 32 is formed on the passivation layer 26. In an example, the field plate electrode 32 includes a plate extension 34 opposed to the electron supply layer 18 via the passivation layer 26 and a gate opposing portion 36 opposed to the gate layer 22 via the passivation layer 26. The field plate electrode 32 further includes a source connector 38 opposed to the electron supply layer 18 via the passivation layer 26 at a position closer to the source electrode 28 than the gate opposing portion 36 is. In an example, the plate extension 34, the gate opposing portion 36, and the source connector 38 are formed integrally. The plate extension 34 and the source electrode 28 are located at opposite sides of the gate opposing portion 36 in the X-direction. That is, the plate extension 34 is located in the X-direction closer to the drain electrode 30 than the gate opposing portion 36 is. The plate extension 34 is separated from the drain electrode 30 in the X-direction. The gate opposing portion 36 is opposed to the gate electrode 24 via the passivation layer 26.

The plate extension 34 has a plate distal surface 34A opposed to the drain electrode 30 in plan view. The plate distal surface 34A extends in the Y-direction in plan view. The plate distal surface 34A is located between the gate layer 22 and the drain electrode 30 in the X-direction. The dimension of the field plate electrode 32 in the X-direction is set in accordance with the position of the plate distal surface 34A in the X-direction. The dimension of the field plate electrode 32 is set in accordance with a necessary switching speed and a necessary breakdown voltage of the nitride semiconductor device 10. In other words, the position of the plate distal surface 34A in the X-direction is set in accordance with the necessary switching speed and the necessary breakdown voltage of the nitride semiconductor device 10.

The gate opposing portion 36 is formed of a region of the field plate electrode 32 that overlaps the gate layer 22 in plan view. Thus, in plan view, the gate opposing portion 36 is smaller than the plate extension 34 in the dimension in the X-direction. In plan view, the dimension of the gate opposing portion 36 in the X-direction is equal to the width of (dimension in the X-direction) of the gate layer 22 extending in the Y-direction.

The source connector 38 is formed of the field plate electrode 32 in a region between the source electrode 28 and the gate opposing portion 36 in the X-direction. The source electrode 28 is formed of a portion that is in contact with the electron supply layer 18. Thus, in plan view, the source connector 38 is formed of the field plate electrode 32 in a region between the first opening 26A and the gate opposing portion 36 in the X-direction.

As shown in FIG. 2, the field plate electrode 32 has an opening 40. In an example, at least a portion of the opening 40 is formed in the plate extension 34. In the first embodiment, the opening 40 is located in the plate extension 34. The opening 40 is not formed in the gate opposing portion 36.

In the first embodiment, the opening 40 is a recess 42 recessed from the plate distal surface 34A toward the gate layer 22. The recess 42 extends so as to have a width in the Y-direction and a depth in the X-direction. The recess 42 is open toward the drain electrode 30. In the example shown in FIG. 2, the recess 42 includes multiple recesses 42 separated from each other in the Y-direction. In an example, the recesses 42 are arranged at equal pitches. The recesses 42 have the same width. The recesses 42 have the same depth.

As shown in FIG. 5, each recess 42 includes two side surfaces 44 and a bottom surface 46 joining the two side surfaces 44. In plan view, the two side surfaces 44 are separated from each other in the Y-direction. Each side surface 44 extends in the X-direction in plan view. Thus, the two side surfaces 44 extend parallel to each other. That is, in the example shown in FIG. 5, the width of the recess 42 in the Y-direction is constant from the opening in the plate distal surface 34A of the plate extension 34 to the bottom surface 46.

As shown in FIGS. 4 and 5, the bottom surface 46 of the recess 42 is located in the X-direction closer to the drain electrode 30 than a side surface 22X of the gate layer 22 is. The position of the bottom surface 46 in the X-direction, that is, a depth H of the recess 42, is set in accordance with the necessary switching speed of the nitride semiconductor device 10 in a range located toward the drain electrode 30 from the side surface 22X of the gate layer 22 in the X-direction. The depth H is defined in plan view by a distance from the plate distal surface 34A to the bottom surface 46 of the recess 42 in the X-direction.

In an example, in plan view, the depth H of the recess 42 is greater than a width W of the recess 42. In an example, in plan view, the depth H of the recess 42 is greater than ½ of a dimension L of the plate extension 34 in the X-direction. In plan view, the dimension L of the plate extension 34 in the X-direction is defined by a distance in the X-direction to the plate distal surface 34A from one of the opposite surfaces of the gate layer 22 in the X-direction located closer to the plate distal surface 34A.

In the example shown in FIG. 5, the width W of the recess 42 is equal to a distance D between recesses 42. The distance D between recesses 42 is defined by a distance in the Y-direction, when a first recess 42 and a second recess 42 are located adjacent to each other in the Y-direction, from one of the side surfaces 44 of the first recess 42 located closer to the second recess 42 to one of the side surfaces 44 of the second recess 42 located closer to the first recess 42.

The double-dashed lines shown in FIG. 6 indicate a depletion layer formed in the field plate electrode 32 when drain-source voltage is applied. As shown in FIG. 6, the distance between the two side surfaces 44 in the X-direction, that is, the width W of the recess 42, is set so as to join portions of a depletion layer extending from the plate distal surface 34A, the bottom surface 46, and each side surface 44.

### Method for Manufacturing Nitride Semiconductor Device

One example of a method for manufacturing the nitride semiconductor device 10 will now be described.

The method for manufacturing the nitride semiconductor device 10 includes forming the buffer layer 14 on the semiconductor substrate 12, forming the electron transit layer 16 on the buffer layer 14, and forming the electron supply layer 18 on the electron transit layer 16.

More specifically, the buffer layer 14, the electron transit layer 16, and the electron supply layer 18 are sequentially formed on the semiconductor substrate 12. The semiconductor substrate 12 is, for example, a Si substrate. The buffer layer 14, the electron transit layer 16, and the electron supply layer 18 may be, for example, epitaxially grown using a metal organic chemical vapor deposition (MOCVD) process. The buffer layer 14 may be, for example, a multilayer buffer layer. The multilayer buffer layer may include an AlN layer (first buffer layer) formed on the semiconductor substrate 12 and a graded AlGaN layer (second buffer layer) formed on the AlN layer. The electron transit layer 16 is, for example, a GaN layer. The electron supply layer 18 is, for example, an AlGaN layer. Thus, the electron supply layer 18 is composed of a nitride semiconductor having a band gap that is larger than that of the electron transit layer 16.

The method for manufacturing the nitride semiconductor device 10 further includes forming the gate layer 22 on the electron supply layer 18, forming the gate electrode 24 on the gate layer 22, and forming the passivation layer 26 on the electron supply layer 18, the gate layer 22, and the gate electrode 24.

More specifically, a nitride semiconductor layer is formed on the electron supply layer 18. The nitride semiconductor layer may be epitaxially grown through a MOCVD process. The nitride semiconductor layer may be formed from a nitride semiconductor containing an acceptor impurity. The acceptor impurity is, for example, Mg. The nitride semiconductor layer is, for example, a GaN layer. The gate electrode 24 is formed on the nitride semiconductor layer. Next, a mask is formed to cover the upper surface and the side surfaces of the gate electrode 24 and a region of the nitride semiconductor layer surrounding the gate electrode 24. The mask is used to etch the nitride semiconductor layer. This forms the gate layer 22. Subsequently, the mask is removed. The passivation layer 26 may be, for example, a SiN layer formed through a low-pressure chemical vapor deposition (LPCVD). When the passivation layer 26 is etched, the first opening 26A and the second opening 26B are formed.

The method for manufacturing the nitride semiconductor device 10 includes a step for forming the source electrode 28, the drain electrode 30, and the field plate electrode 32.

More specifically, a metal layer is formed on the passivation layer 26. The metal layer fills the first opening 26A and the second opening 26B and contacts the electron supply layer 18 through the first opening 26A and the second opening 26B. In an example, the metal layer may include at least one of a Ti layer, a TiN layer, an Al layer, an AlSiCu layer, and an AlCu layer.

The metal layer is selectively removed by lithography and etching to form the source electrode 28, the drain electrode 30, and the field plate electrode 32. In this step, the opening 40 is formed in the field plate electrode 32. The steps described above manufacture the nitride semiconductor device 10.

The opening 40 does not necessarily have to be formed simultaneously with the source electrode 28 and the drain electrode 30. In an example, after the source electrode 28 and the drain electrode 30 are formed by lithography and etching of the metal layer, the opening 40 may be formed by lithography and etching of the metal layer. In another example, after the opening 40 is formed by lithography and etching of the metal layer, the source electrode 28 and the drain electrode 30 may be formed by lithography and etching of the metal layer.

### Operation

The operation of the nitride semiconductor device 10 of the first embodiment will now be described.

Extension of the dimension of the field plate electrode in the X-direction reduces the concentration of electric fields between the drain electrode 30 and the source electrode 28 in the X-direction. However, when the dimension of the field plate electrode extends in the X-direction, the parasitic capacitance between the field plate electrode and each of the electron supply layer 18 and the gate layer 22 is increased in accordance with the area of the field plate electrode. The increase in the parasitic capacitance may adversely affect the switching response of the nitride semiconductor device.

In this regard, in the first embodiment, the recesses 42 (openings 40), which are recessed from the plate distal surface 34A of the field plate electrode 32 in the X-direction, are provided. This reduces the parasitic capacitance between the field plate electrode 32 and the electron supply layer 18. In addition, the width W of the recess 42 is set so as to join portions of the depletion layer extending from the two side surfaces 44 of the recesses 42. Thus, even when the recess 42 is formed, the effect of reducing the concentration of electric fields caused by the field plate electrode 32 is likely to be maintained.

### Advantages

The nitride semiconductor device 10 of the first embodiment obtains the following advantages.

(1-1) The nitride semiconductor device 10 includes the electron transit layer 16 composed of a nitride semiconductor, the electron supply layer 18 formed on the electron transit layer 16 and composed of a nitride semiconductor having a band gap that is larger than that of the electron transit layer 16, the gate layer 22 formed on the electron supply layer 18 and composed of a nitride semiconductor including an acceptor impurity, the gate electrode 24 formed on the gate layer 22, the passivation layer 26 covering the electron supply layer 18, the gate layer 22, and the gate electrode 24 and having the first opening 26A and the second opening 26B separated from each other in the X-direction, the gate layer 22 being arranged between the first opening 26A and the second opening 26B, the source electrode 28 in contact with the electron supply layer 18 through the first opening 26A, the drain electrode 30 in contact with the electron supply layer 18 through the second opening 26B, and the field plate electrode 32 formed on the passivation layer 26 and electrically connected to the source electrode 28. The field plate electrode 32 includes the plate extension 34 extending in a region between the gate layer 22 and the drain electrode 30 in plan view and being opposed to the electron supply layer 18 via the passivation layer 26. The opening 40 is formed in the field plate electrode 32. The opening 40 is formed in the plate extension 34.

In this structure, the opening 40 is formed in the plate extension 34. This reduces the parasitic capacitance between the field plate electrode 32 and the electron supply layer 18. Thus, the adverse effect on the switching response of the nitride semiconductor device 10 is reduced.

(1-2) The plate extension 34 has the plate distal surface 34A opposed to the drain electrode 30. The opening 40 is the recess 42 recessed from the plate distal surface 34A toward the gate layer 22. In plan view, the recess 42 extends so as to have a width in the Y-direction, which is orthogonal to the X-direction, and a depth in the X-direction, and is open toward the drain electrode 30.

With this structure, the plate distal surface 34A extends the length of the plate extension 34. Thus, the field plate electrode 32 reduces the concentration of electric fields between the source electrode 28 and the drain electrode 30. In addition, the recess 42 reduces the parasitic capacitance between the field plate electrode 32 and the electron supply layer 18. As described above, the reduction of the concentration of electric fields between the source electrode 28 and the drain electrode 30 and the reduction of the parasitic capacitance between the field plate electrode 32 and the electron supply layer 18 are both achieved.

(1-3) The depth H of the recess 42 is greater than ½ of the dimension L of the plate extension 34 in the X-direction.

In this structure, the recess 42 extends extensively in the X-direction (depth-wise direction). This more effectively reduces the parasitic capacitance between the field plate electrode 32 and the electron supply layer 18.

(1-4) The recess 42 includes multiple recesses 42 separated from each other in the Y-direction.

This structure includes a greater number of recesses 42. Thus, even when the width of each recess 42 is small, the effect on reduction of the parasitic capacitance between the field plate electrode 32 and the electron supply layer 18 is increased. In addition, the small width of the recess 42 facilitates formation of a depletion layer in the entire recess 42. Thus, the effect of the field plate electrode 32 on reduction in electric field intensity is less likely to be decreased.

### Second Embodiment

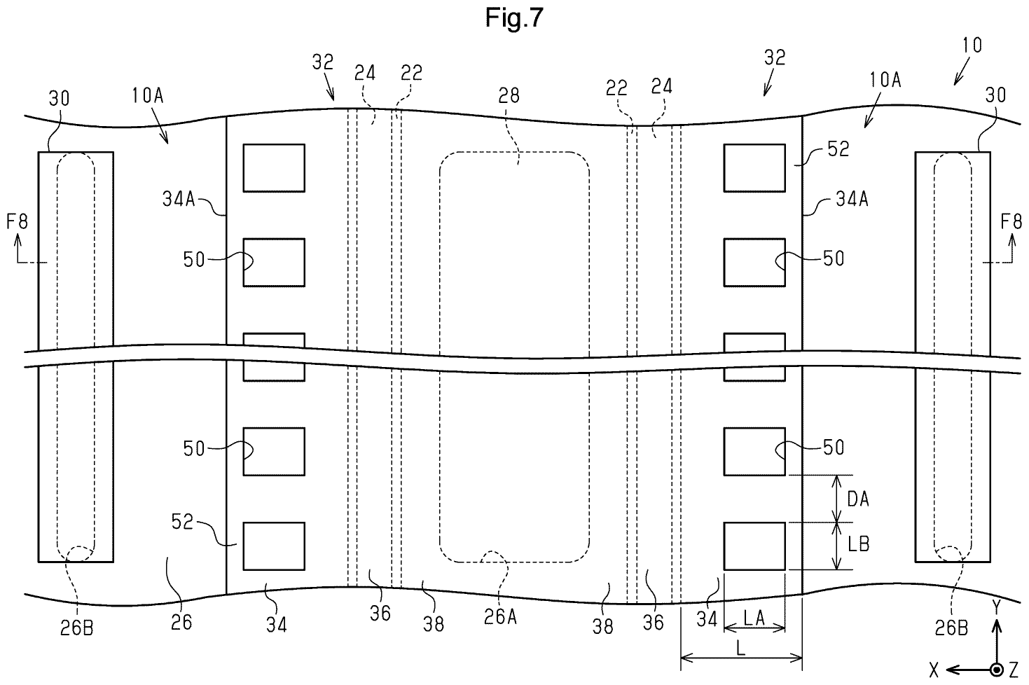

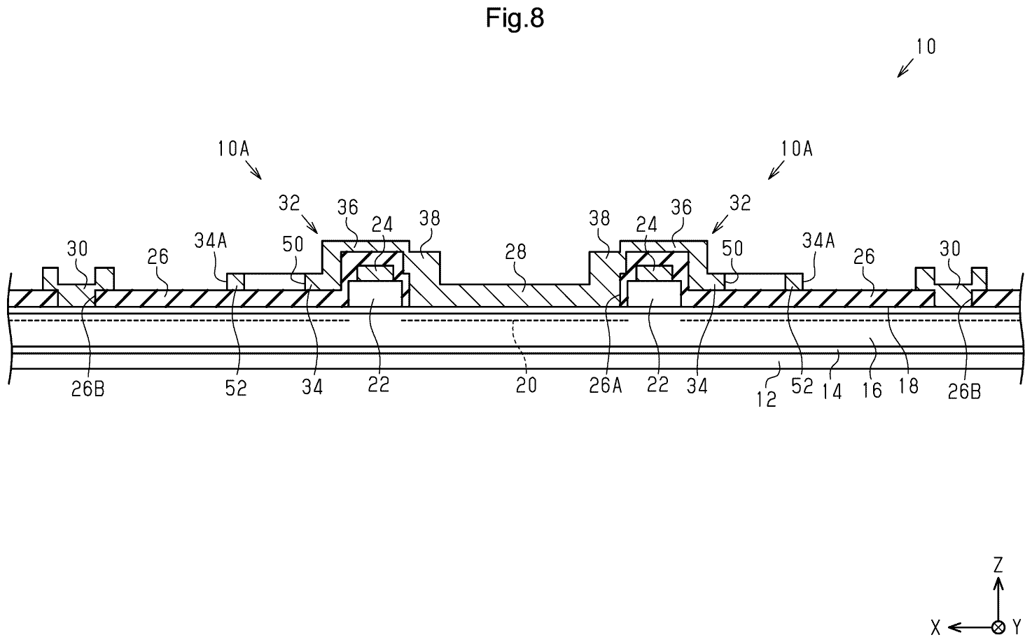

A second embodiment of a nitride semiconductor device 10 will now be described with reference to FIGS. 7 and 8. The nitride semiconductor device 10 of the second embodiment differs from the nitride semiconductor device 10 of the first embodiment in the structure of the field plate electrode 32. In the following description, the differences from the first embodiment will be described in detail. The same reference characters are given to those components that are the same as the corresponding components of the first embodiment. Such components will not be described in detail.

FIG. 7 schematically shows the planar structure of the nitride semiconductor device 10 including the passivation layer 26 and the field plate electrode 32. FIG. 8 schematically shows a cross-sectional structure of the nitride semiconductor device 10 taken along line F8-F8 in FIG. 7.

As shown in FIG. 7, in the second embodiment, the field plate electrode 32 has an opening 50. At least a portion of the opening 50 is formed in the plate extension 34. In the second embodiment, the opening 50 is formed in the plate extension 34. The opening 50 is not formed in the gate opposing portion 36. The opening 50 includes multiple openings 50 separated from each other in the Y-direction. The openings 50 are, for example, arranged at equal pitches.

The openings 50, which differ from the opening 40 (refer to FIG. 5) of the first embodiment, are closed and located closer to the gate electrode 24 (the gate layer 22) than the plate distal surface 34A is.

In the example shown in FIG. 7, each opening 50 is rectangular such that the long sides extend in the X-direction and the short sides extend in the Y-direction in plan view. In an example, the openings 50 are equal in dimension LA in the X-direction. In an example, the dimension LA of the opening 50 in the X-direction is greater than ½ of the dimension L of the plate extension 34 in the X-direction.

The openings 50 each have a dimension LB in the Y-direction that is set so that depletion layers extending in the openings 50 are joined when a drain-source voltage is applied. In an example, the openings 50 are equal in dimension LB in the Y-direction. The dimension LB of each opening 50 in the Y-direction is equal to a distance DA between openings 50. The distance DA is defined by a distance between two openings 50 located adjacent to each other in the Y-direction.

As shown in FIG. 8, the opening 50 is located closer to the gate electrode 24 (the gate layer 22) than the plate distal surface 34A is. Thus, a plate distal portion 52 is formed between the opening 50 and the plate distal surface 34A in the X-direction. As shown in FIG. 7, the plate distal portion 52 extends in the Y-direction.

The dimension LA of the opening 50 in the X-direction may be changed in any manner. In an example, the dimension LA of the opening 50 in the X-direction may be less than or equal to ½ of the dimension L of the plate extension 34 in the X-direction. At least one of the openings 50 may differ in the dimension LA in the X-direction from the other openings 50.

### Advantages

The nitride semiconductor device 10 of the second embodiment obtains the following advantages.

(2-1) The plate extension 34 has the plate distal surface 34A opposed to the drain electrode 30. The opening 50 is closed and is located closer to the gate electrode 24 than the plate distal surface 34A is.

In this structure, the plate distal surface 34A is formed in the entirety of the field plate electrode 32 in the Y-direction. Thus, the field plate electrode 32 has the dimension L in the X-direction along the entirety of the field plate electrode 32 in the Y-direction. Accordingly, the field plate electrode 32 reduces the concentration of electric fields more effectively.

(2-2) The dimension LA of the opening 50 in the X-direction is greater than ½ of the dimension L of the plate extension 34 in the X-direction.

In this structure, the opening 50 extends extensively in the X-direction. Thus, the parasitic capacitance between the field plate electrode 32 and the electron supply layer 18 is reduced more effectively.

(2-3) The opening 50 includes multiple openings 50 separated from each other in the Y-direction.

This structure includes a greater number of openings 50. Thus, even when the width (dimension in the Y-direction) of each opening 50 is small, the effect on reduction of the parasitic capacitance between the field plate electrode 32 and the electron supply layer 18 is increased. In addition, the small width of the opening 50 facilitates formation of a depletion layer in the entire opening 50. Thus, the effect of the field plate electrode 32 on reduction in electric field concentration is less likely to be decreased.

### Third Embodiment

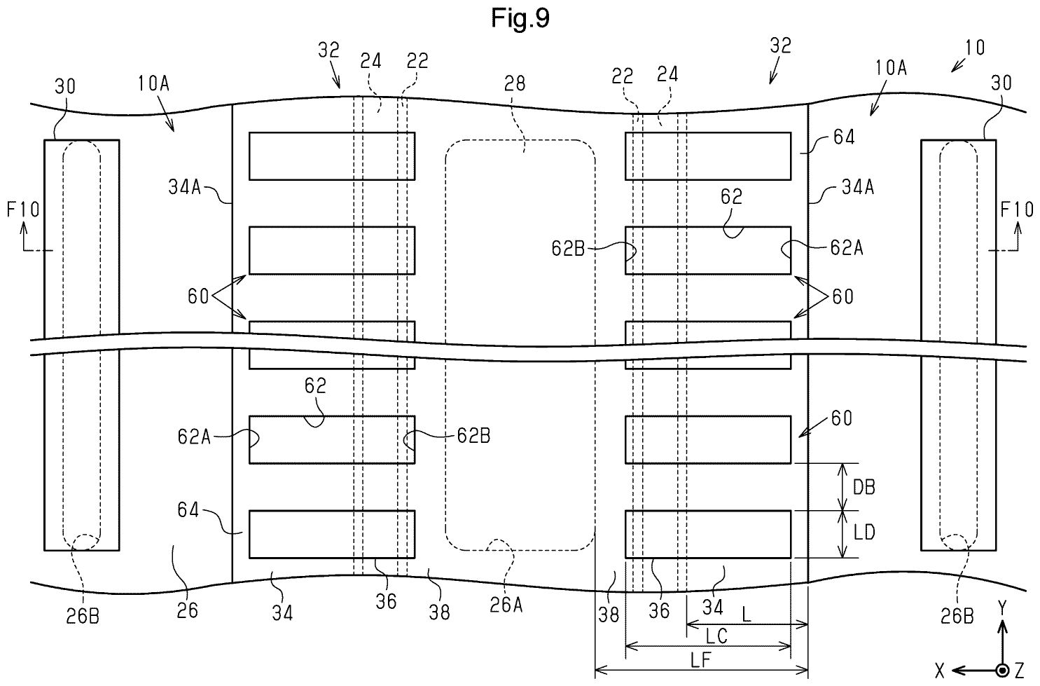

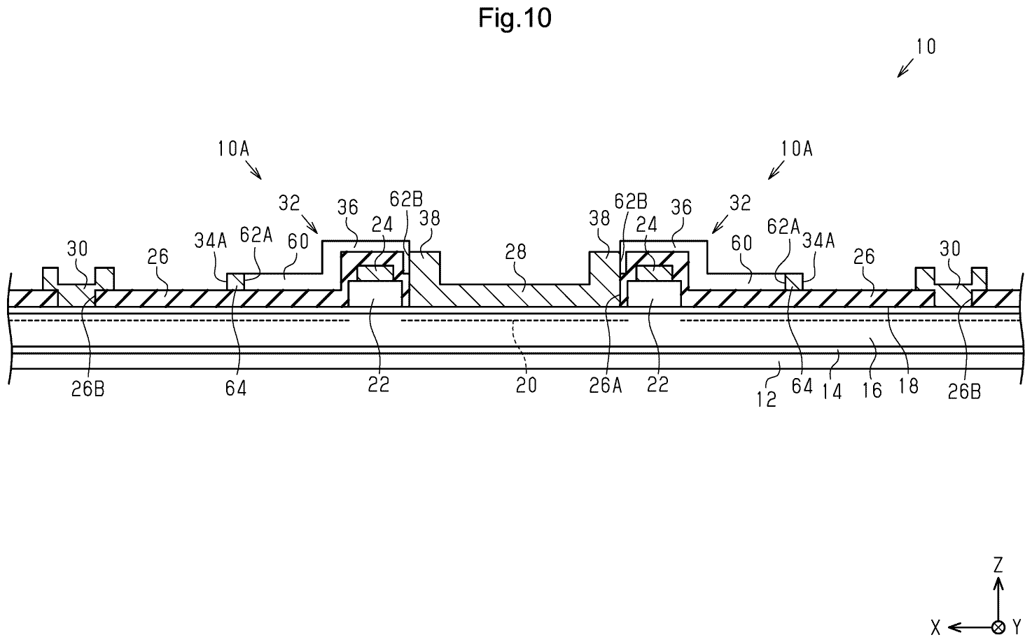

A third embodiment of a nitride semiconductor device 10 will now be described with reference to FIGS. 9 and 10. The nitride semiconductor device 10 of the third embodiment differs from the nitride semiconductor device 10 of the second embodiment in the structure of the field plate electrode 32. In the following description, the differences from the second embodiment will be described in detail. The same reference characters are given to those components that are the same as the corresponding components of the second embodiment. Such components will not be described in detail.

FIG. 9 schematically shows the planar structure of the nitride semiconductor device 10 including the passivation layer 26 and the field plate electrode 32. FIG. 10 schematically shows a cross-sectional structure of the nitride semiconductor device 10 taken along line F10-F10 in FIG. 9.

As shown in FIG. 9, in the third embodiment, the field plate electrode 32 has an opening 60. At least a portion of the opening 60 is formed in the plate extension 34. In the third embodiment, the opening 60 extends over the plate extension 34 and the gate opposing portion 36. In the example shown in FIG. 9, the opening 60 extends over the plate extension 34, the gate opposing portion 36, and the source connector 38. That is, the opening 60 extends across the gate opposing portion 36. The opening 60 includes multiple openings 60 separated from each other in the Y-direction. The openings 60 are, for example, arranged at equal pitches.

In the same manner as the openings 50 (refer to FIG. 7) of the second embodiment, the openings 60 are closed and located closer to the gate electrode 24 (the gate layer 22) than the plate distal surface 34A is. Each opening 60 is rectangular such that the long sides extend in the X-direction and the short sides extend in the Y-direction in plan view. The opening 60 has a dimension LC in the X-direction that is greater than the dimension L of the plate extension 34 in the X-direction. In an example, the dimension LC of the opening 60 in the X-direction is greater than ½ of a dimension LF of the field plate electrode 32 in the X-direction.

The openings 60 each have a dimension LD in the Y-direction that is set so that depletion layers extending in the openings 60 are joined when a drain-source voltage is applied. In an example, the openings 60 are equal in dimension LD in the Y-direction. The dimension LD of each opening 60 in the Y-direction is equal to a distance DB between openings 60. The distance DB is defined by a distance between two openings 60 located adjacent to each other in the Y-direction.

As shown in FIG. 10, the opening 60 is located closer to the gate electrode 24 (the gate layer 22) than the plate distal surface 34A is. Thus, a plate distal portion 64 is formed between the opening 60 and the plate distal surface 34A in the X-direction. As shown in FIG. 9, the plate distal portion 64 extends in the Y-direction.

As shown in FIGS. 9 and 10, the field plate electrode 32 includes an inner surface 62 defining each opening 60. The inner surface 62 includes opposite end surfaces in the X-direction, namely, a first end surface 62A and a second end surface 62B. The first end surface 62A is a side surface forming a plate distal portion 64 and is formed in the plate extension 34. The second end surface 62B is formed in the source connector 38. That is, in plan view, the second end surface 62B is located closer to the gate layer 22 than the source electrode 28 is. In other words, in plan view, the second end surface 62B is located between the source electrode 28 and the gate layer 22 in the X-direction.

The position of the first end surface 62A and the second end surface 62B in the X-direction may be changed in any manner. At least one of the openings 60 may differ in the position of the first end surface 62A in the X-direction from the other openings 60. At least one of the openings 60 may differ in the position of the second end surface 62B in the X-direction from the other openings 60. Consequently, at least one of the openings 60 may differ in the dimension LC in the X-direction from the other openings 60.

### Advantages

The nitride semiconductor device 10 of the third embodiment obtains the following advantages.

(3-1) The field plate electrode 32 includes the gate opposing portion 36 opposed to the gate layer 22 via the passivation layer 26. The opening 60 extends over the plate extension 34 and the gate opposing portion 36.

In this structure, the opening 60 extends over the plate extension 34 and the gate opposing portion 36. Thus, the opening 60 extensively extends in the X-direction. The effect on reduction of the parasitic capacitance between the field plate electrode 32 and the electron supply layer 18 is increased.

(3-2) The opening 60 is closed and is located closer to the gate electrode 24 than the plate distal surface 34A is.

In this structure, the plate distal surface 34A is formed in the entirety of the field plate electrode 32 in the Y-direction. Thus, the field plate electrode 32 has the dimension L in the X-direction along the entirety of the field plate electrode 32 in the Y-direction. Accordingly, the field plate electrode 32 reduces the concentration of electric fields more effectively.

(3-3) The opening 60 includes multiple openings 60 separated from each other in the Y-direction.

This structure includes a greater number of openings 60. Thus, even when the width (dimension in the Y-direction) of each opening 60 is small, the effect on reduction of the parasitic capacitance between the field plate electrode 32 and the electron supply layer 18 is increased. In addition, the small width of the opening 60 facilitates formation of a depletion layer in the entire opening 60. Thus, the effect of the field plate electrode 32 on reduction in electric field concentration is less likely to be decreased.

(3-4) The opening 60 extends over the plate extension 34, the gate opposing portion 36, and the source connector 38.

In this structure, the opening 60 extends over the plate extension 34, the gate opposing portion 36, and the source connector 38. Thus, the opening 60 extensively extends in the X-direction. The effect on reduction of the parasitic capacitance between the field plate electrode 32 and the electron supply layer 18 is increased.

### Modified Examples

The above embodiments may be modified as described below. The above embodiments and the modified examples described below may be combined as long as there is no technical contradiction. In the modified examples described hereafter, same reference characters are given to those components that are the same as the corresponding components of the above embodiments. Such components will not be described in detail.

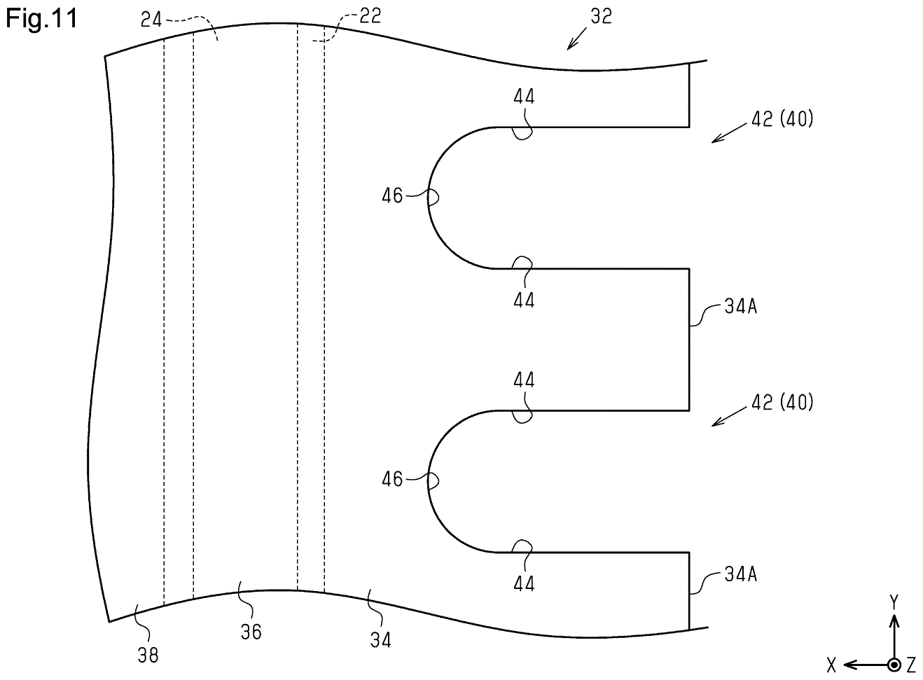

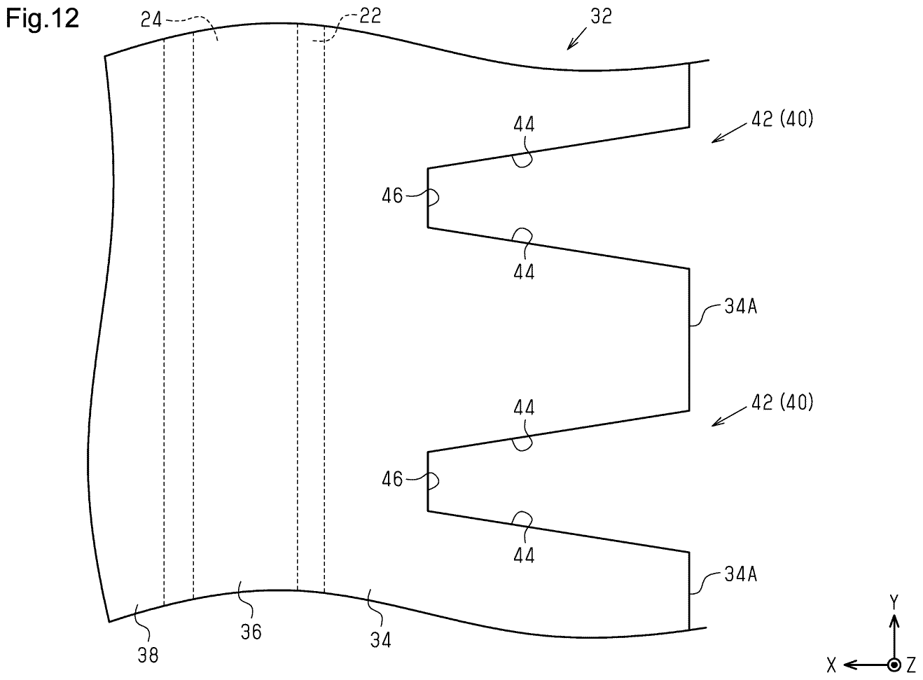

In the first embodiment, the recess 42, which is the opening 40 in the field plate electrode 32, may be changed in any manner. The recess 42 may be changed, for example, as recess 42 shown in FIG. 11 and recess 42 shown in FIG. 12.

As shown in FIG. 11, the bottom surface 46 of the recess 42 may be curved. In the example shown in FIG. 11, the bottom surface 46 may be curved and recessed toward the gate layer 22 in plan view. In plan view, the portion of the bottom surface 46 located closest to the gate layer 22 is located closer to the drain electrode 30 (refer to FIG. 2) than the gate layer 22 is.

In this structure, the side surfaces 44 and the bottom surface 46 of the recess 42 do not have a corner and thus are curved. The curved bottom surface 46 facilitates joining of a depletion layer extending from the two side surfaces 44. Thus, the field plate electrode 32 readily reduces the concentration of electric fields generated between the drain electrode 30 and the source electrode 28.

As shown in FIG. 12, the recess 42 may be tapered so that the two side surfaces 44 approach each other from the plate distal surface 34A toward the bottom surface 46.

This structure facilitates joining of a depletion layer from the two side surfaces 44 in the vicinity of the bottom surface 46 of the recess 42. Thus, the field plate electrode 32 readily reduces the concentration of electric fields generated between the drain electrode 30 and the source electrode 28.

The shape of the recess 42 shown in FIG. 11 and the shape of the recess 42 shown in FIG. 12 may be combined. More specifically, the recess 42 may include the bottom surface 46 that is recessed toward the gate layer 22 and be tapered by the two side surfaces 44 that approach each other from the plate distal surfaces 34A toward the bottom surface 46.

In the first embodiment, the relationship of the width W of a recess 42 with the distance D between recesses 42 may be changed in any manner.

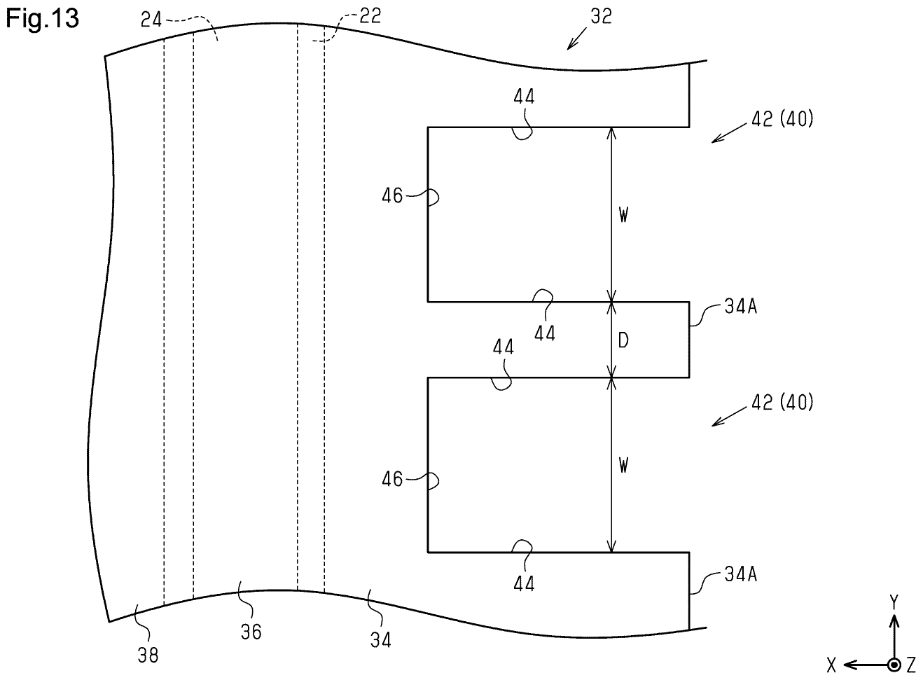

In an example, as shown in FIG. 13, the width W of the recess 42 may be greater than the distance D between the recesses 42.

This structure reduces the parasitic capacitance caused by the field plate electrode 32. Thus, the adverse effect on the switching response of the nitride semiconductor device 10 is reduced.

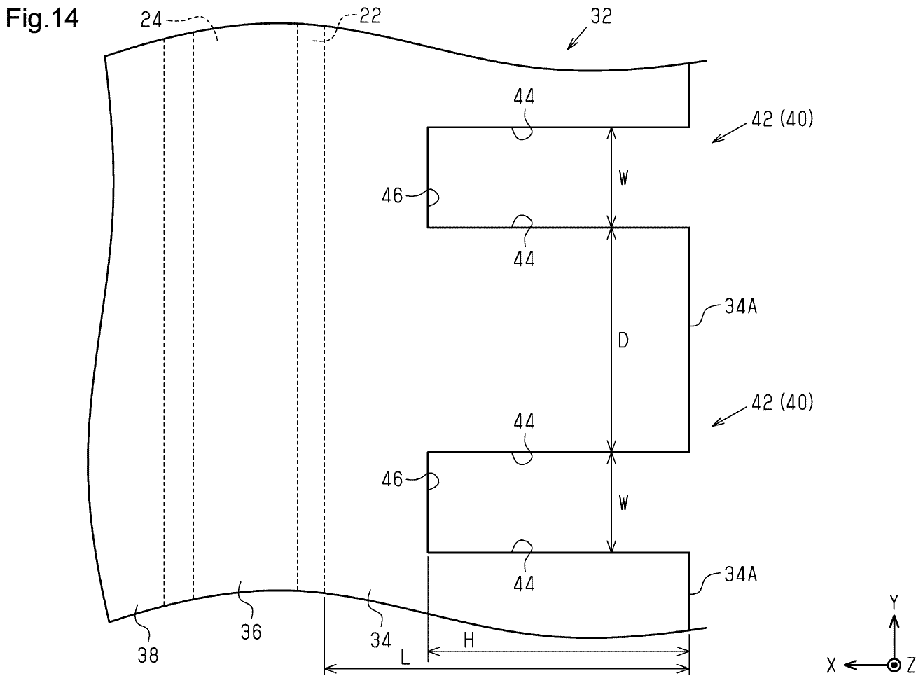

In another example, as shown in FIG. 14, the distance D between the recesses 42 may be greater than the width W of the recess 42.

With this structure, the field plate electrode 32 reduces the concentration of electric fields more effectively.

Also, in the second embodiment and the third embodiment, the relationship of the dimensions LB and LD of the openings 50 and 60 in the Y-direction with the distances DA and DB between the openings 50 and 60 may be changed in any manner.

In an example, the dimension LB of an opening 50 in the Y-direction may be greater than the distance DA between openings 50. In an example, the dimension LB of an opening 50 in the Y-direction may be less than the distance DA between openings 50.

In an example, the dimension LD of an opening 60 in the Y-direction may be greater than the distance DB between openings 60. In an example, the dimension LD of an opening 60 in the Y-direction may be less than the distance DB between openings 60.

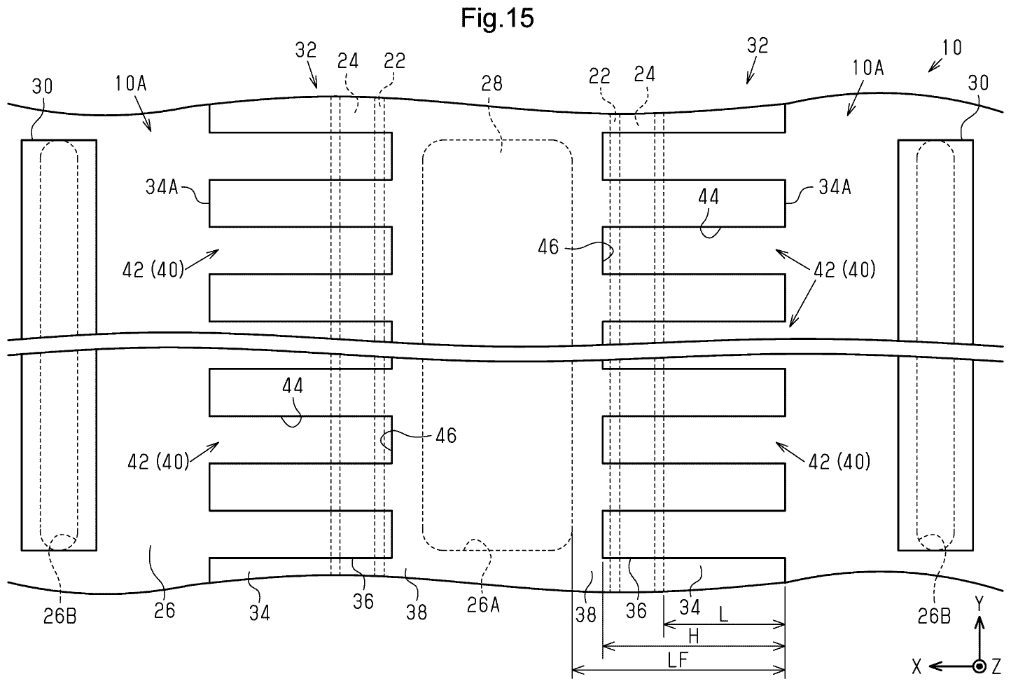

In the first embodiment, the depth H of the recess 42 may be changed in any manner. In an example, as shown in FIG. 15, the recess 42 may extend from the plate distal surface 34A longer than the plate extension 34 does. The recess 42 may extend over the plate extension 34 and the gate opposing portion 36.

With this structure, the depth H of the recess 42 is increased. This reduces the parasitic capacitance caused by the field plate electrode 32. Thus, the adverse effect on the switching response of the nitride semiconductor device 10 is reduced.

In the first embodiment, the bottom surfaces 46 of the recesses 42 are located at the same position in the X-direction. However, this is not a limitation. In an example, the bottom surface 46 of at least one of the recesses 42 may differ in the position in the X-direction from the bottom surfaces 46 of the other recesses 42.

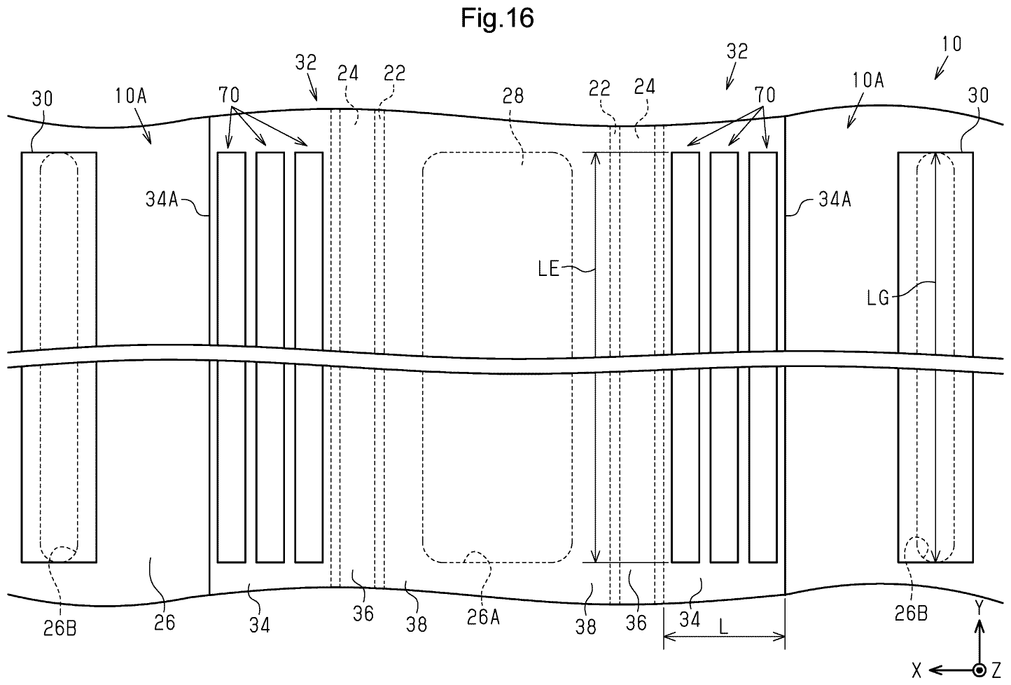

In the embodiments described above, the layout, shape, and size of the openings in the field plate electrode 32 may be changed in any manner. Modified examples will be described below with reference to the drawings. FIGS. 16 to 23 each show the planar structure of a field plate electrode 32.

### First Modified Example

As shown in FIG. 16, the field plate electrode 32 has an opening 70. The opening 70 is formed in the plate extension 34. The opening 70 is not formed in the gate opposing portion 36. The opening 70 includes multiple openings 70 separated from each other in the X-direction. Each opening 70 is rectangular such that the short sides extend in the X-direction and the long sides extend in the Y-direction in plan view. The opening 70 is belt-shaped and elongated in the Y-direction. In the example shown in FIG. 16, three openings 70 are formed in the plate extension 34 and separated from each other in the X-direction.

Each opening 70 has a dimension LE in the Y-direction that is greater than the dimension L of the plate extension 34 in the X-direction. In an example, the opening 70 is formed in the entire region where the gate layer 22 is opposed to the drain electrode 30 in the X-direction. Thus, the dimension LE of the opening 70 in the Y-direction may be greater than or equal to the dimension LG of the drain electrode 30 in the Y-direction.

### Second Modified Example

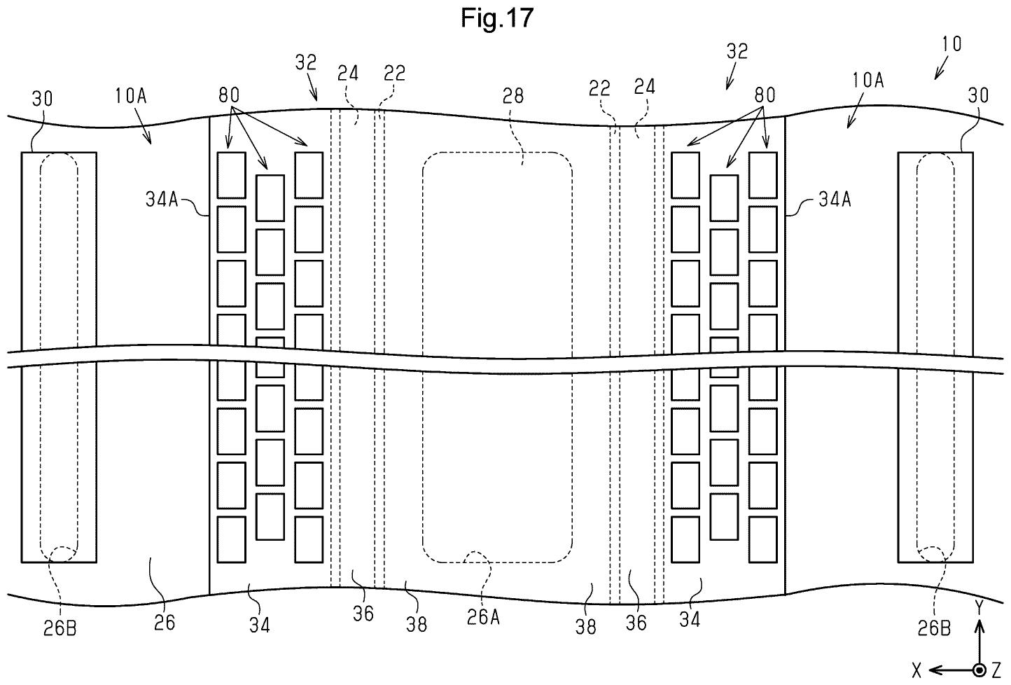

As shown in FIG. 17, the field plate electrode 32 has an opening 80. The opening 80 is located in the plate extension 34. The opening 80 is not formed in the gate opposing portion 36. The opening 80 includes multiple openings 80 separated from each other in the X-direction and Y-direction. In the example shown in FIG. 17, the openings 80 are separated from each other in the Y-direction in each row, and three rows of the openings 80 are arranged and spaced apart from each other in the X-direction. The openings 80 in the row in the Y-direction that is located closest to the plate distal surface 34A are in the same position in the Y-direction as the openings 80 in the row in the Y-direction that is located closest to the source electrode 28. Among the three rows of the openings 80 in the Y-direction, in the middle row of the openings 80 in the X-direction, the openings 80 are misaligned in the Y-direction from the openings 80 in the row located closest to the plate distal surface 34A and the openings 80 in the row located closest to the source electrode 28.

### Third Modified Example

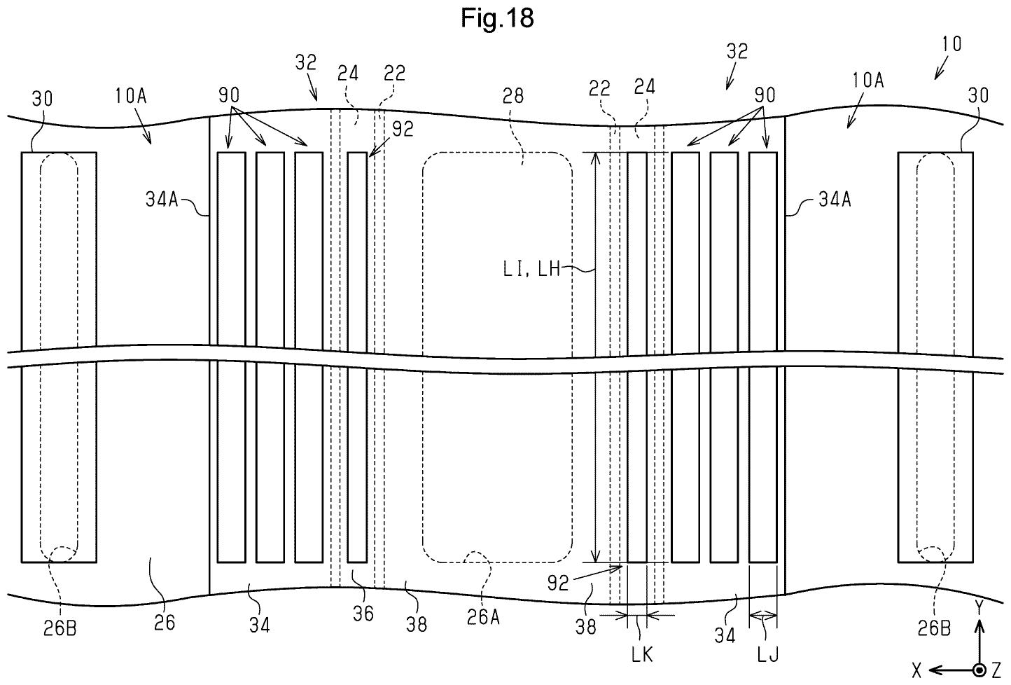

As shown in FIG. 18, the field plate electrode 32 has a first opening 90 and a second opening 92. The first opening 90 is located in the plate extension 34. Thus, at least a portion of the opening is located in the plate extension 34. The second opening 92 is located in the gate opposing portion 36. In other words, the second opening 92 is located at a position that overlaps the gate layer 22 in plan view. Thus, in the example shown in FIG. 18, at least a portion of the opening is located at a position that overlaps the gate layer 22 in plan view. In other words, the opening is located in at least the gate opposing portion 36. Thus, in the example shown in FIG. 18, the opening is located in the plate extension 34 and a position that overlaps the gate layer 22 in plan view.

The first opening 90 includes multiple openings 90 separated from each other in the X-direction. Each first opening 90 is rectangular such that the short sides extend in the X-direction and the long sides extend in the Y-direction in plan view. The first opening 90 is belt-shaped and elongated in the Y-direction. In the example shown in FIG. 18, three first openings 90 are formed in the plate extension 34 and separated from each other in the X-direction. In the example shown in FIG. 18, the three first openings 90 have the same shape and size as the three openings 70 shown in FIG. 16.

The second opening 92 is rectangular such that the short sides extend in the X-direction and the long sides extend in the Y-direction in plan view. The second opening 92 is belt-shaped and elongated in the Y-direction. In the region in which the second opening 92 overlaps the gate layer 22 in plan view, the second opening 92 is formed in the entire region where the gate layer 22 is opposed to the drain electrode 30 in the X-direction.

In the example shown in FIG. 18, the dimension LI of the second opening 92 in the Y-direction is equal to the dimension LH of the first opening 90 in the Y-direction. In other words, the first opening 90 is formed in the entire region of the plate extension 34 where the gate layer 22 and the drain electrode 30 are opposed to each other in the X-direction. In the example shown in FIG. 18, a dimension LK of the second opening 92 in the X-direction is smaller than a dimension LJ of the first opening 90 in the X-direction. The dimensions LH and LJ of the first opening 90 and the dimensions LI and LK of the second openings 92 may be changed in any manner. In an example, the dimension LK of the second opening 92 in the X-direction may be greater than the dimension LJ of the first opening 90 in the X-direction.

### Fourth Modification

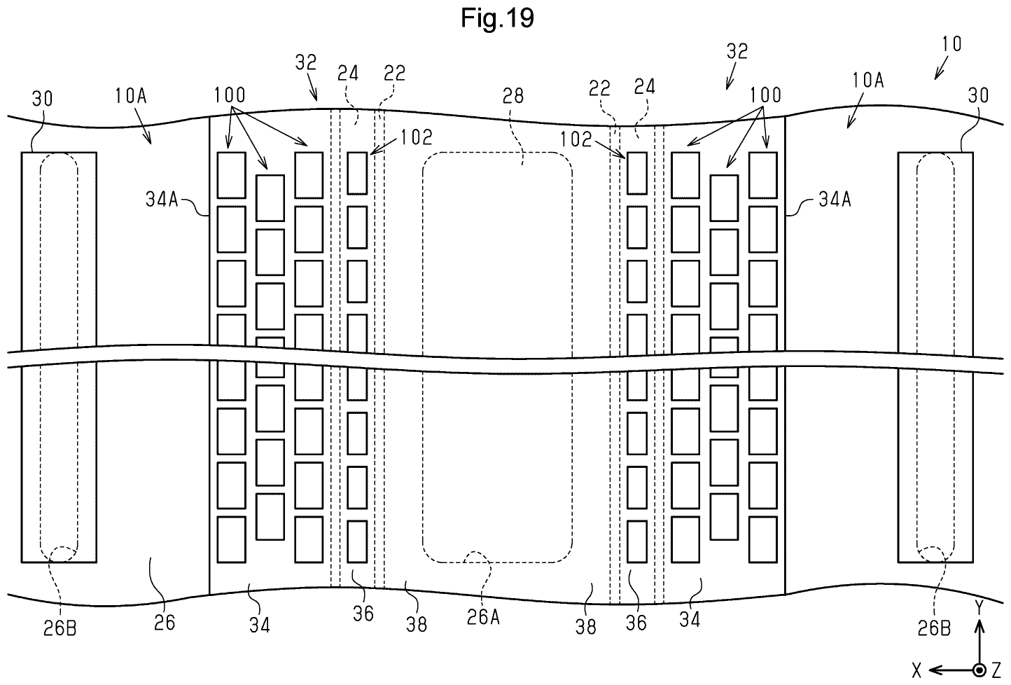

As shown in FIG. 19, the field plate electrode 32 has a first opening 100 and a second opening 102. The first opening 100 is located in the plate extension 34. Thus, at least a portion of the opening is located in the plate extension 34. The second opening 102 is located in the gate opposing portion 36. In other words, the second opening 102 overlaps the gate layer 22 in plan view. Thus, in the example shown in FIG. 19, at least a portion of the opening is located at a position that overlaps the gate layer 22 in plan view. In other words, the opening is located in at least the gate opposing portion 36. Thus, in the example shown in FIG. 19, the opening is located in the plate extension 34 and a location that overlaps the gate layer 22 in plan view.

The first opening 100 includes multiple first openings 100 separated from each other in the X-direction and Y-direction. In the example shown in FIG. 19, the first openings 100 are separated from each other in the Y-direction in each row, and three rows of the first openings 100 are arranged and spaced apart from each other in the X-direction. The layout of the first openings 100 is the same as the layout of the openings shown in FIG. 17. The shape and the size of the first opening 100 are the same as the shape and size of the opening 80.

The second opening 102 includes multiple second openings 102 separated from each other in the Y-direction. In the example shown in FIG. 19, the shape of the second opening 102 is the same as the shape of the first opening 100. However, the second opening 102 is smaller in size than the first opening 100. More specifically, the dimension of each second opening 102 in the X-direction is smaller than the dimension of each first opening 100 in the X-direction. The dimension of each second opening 102 in the Y-direction is smaller than the dimension of each first opening 100 in the Y-direction.

The shape and size of the first opening 100 and the second opening 102 may be changed in any manner. In an example, the first opening 100 may have the same shape and size as the second opening 102.

### Fifth Modified Example

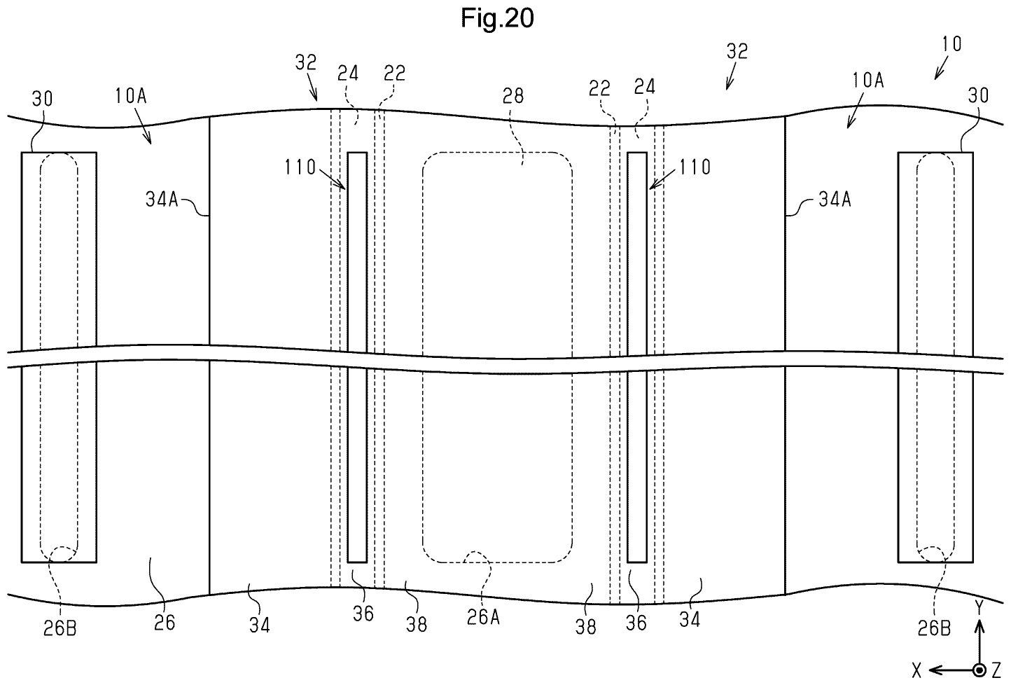

As shown in FIG. 20, the field plate electrode 32 has an opening 110. The opening 110 is located in the gate opposing portion 36. In other words, the opening 110 is located at a position that overlaps the gate layer 22 in plan view. The opening 110 is not arranged in the plate extension 34. Thus, in the example shown in FIG. 20, at least a portion of the opening is located at a position that overlaps the gate layer 22 in plan view. In other words, the opening is located in at least the gate opposing portion 36.

The opening 110 is rectangular such that the short sides extend in the X-direction and the long sides extend in the Y-direction in plan view. The opening 110 is belt-shaped and elongated in the Y-direction. In the region in which the opening 110 overlaps the gate layer 22 in plan view, the second opening 92 is formed in the entire region where the gate layer 22 is opposed to the drain electrode 30 in the X-direction. The opening 110 of the fifth modified example may be applied to the first and second embodiments.

### Sixth Modification

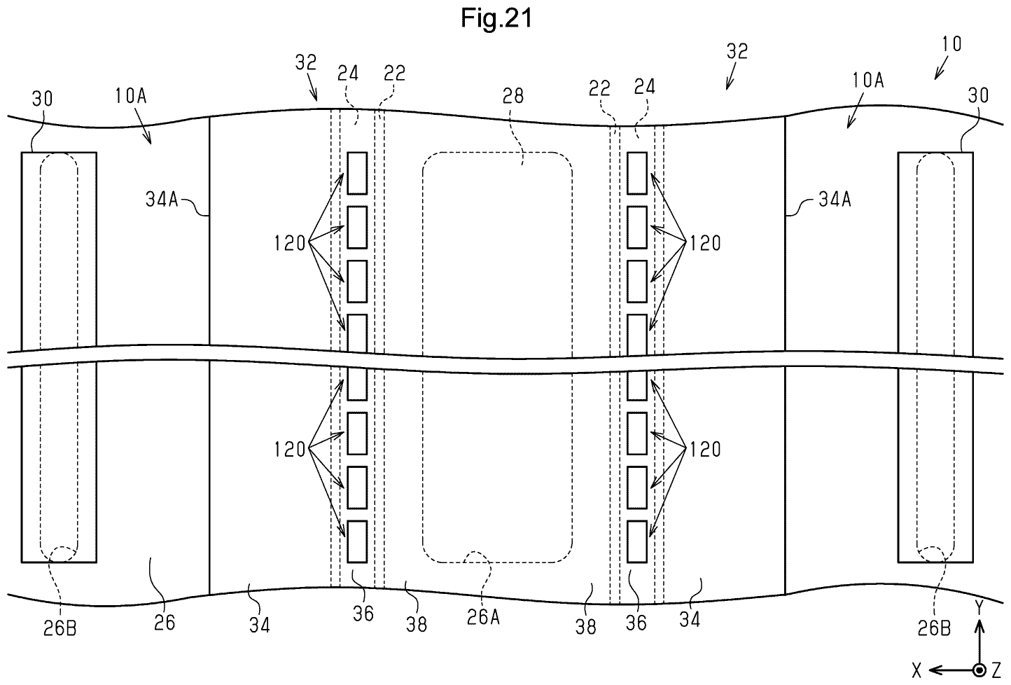

As shown in FIG. 21, the field plate electrode 32 has an opening 120. The opening 120 may be located in the gate opposing portion 36. In other words, the opening 120 is located at a position that overlaps the gate layer 22 in plan view. The opening 120 is not arranged in the plate extension 34. Thus, in the example shown in FIG. 21, at least a portion of the opening is located at a position that overlaps the gate layer 22 in plan view. In other words, the opening is located in at least the gate opposing portion 36. The opening 120 includes multiple openings 120 separated from each other in the Y-direction. Each opening 120 is rectangular such that the short sides extend in the X-direction and the long sides extend in the Y-direction in plan view. The opening 120 of the sixth modified example may be applied to the first and second embodiments.

### Seventh Modified Example

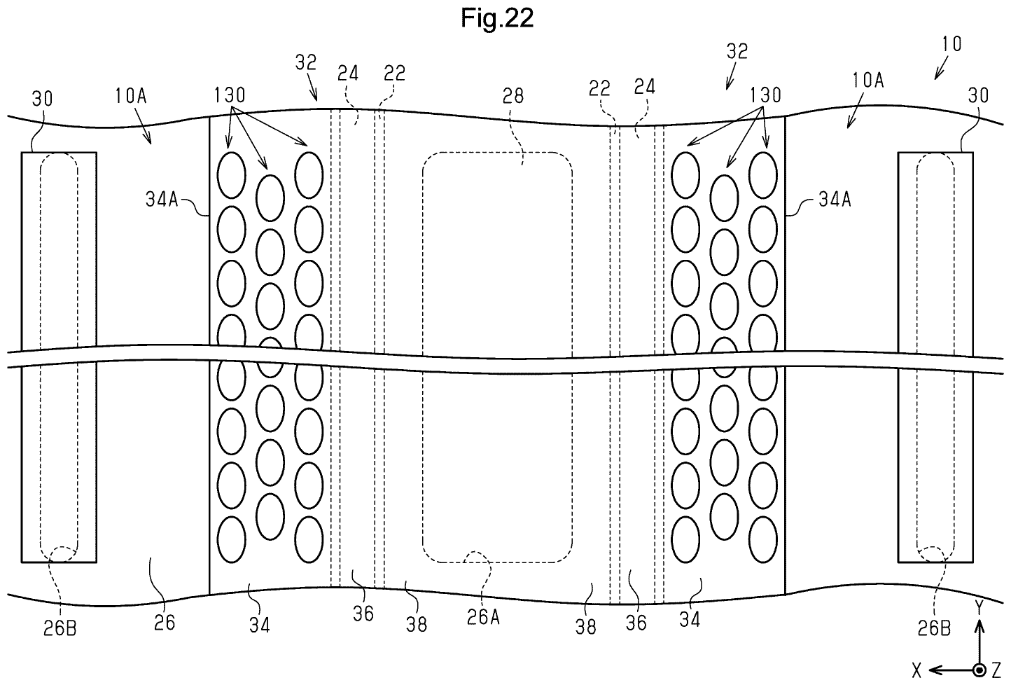

As shown in FIG. 22, the field plate electrode 32 has an opening 130. The opening 130 is located in the plate extension 34. The opening 130 is not formed in the gate opposing portion 36. The opening 130 includes multiple openings 130 separated from each other in the X-direction and Y-direction. In the example shown in FIG. 22, the openings 130 are separated from each other in the Y-direction in each row, and three rows of the openings 130 are arranged and spaced apart from each other in the X-direction. The layout of the openings 130 is the same as the layout of the openings 80 shown in FIG. 17.

The opening 130 is an ellipse in plan view. In the example shown in FIG. 22, in plan view, each opening 130 is elliptical so that the short axis extends in the X-direction and the long axis extends in the Y-directions. The opening 130 is not limited to the elliptical shape and may be circular. The opening 130 may be polygonal in plan view.

### Eighth Modified Example

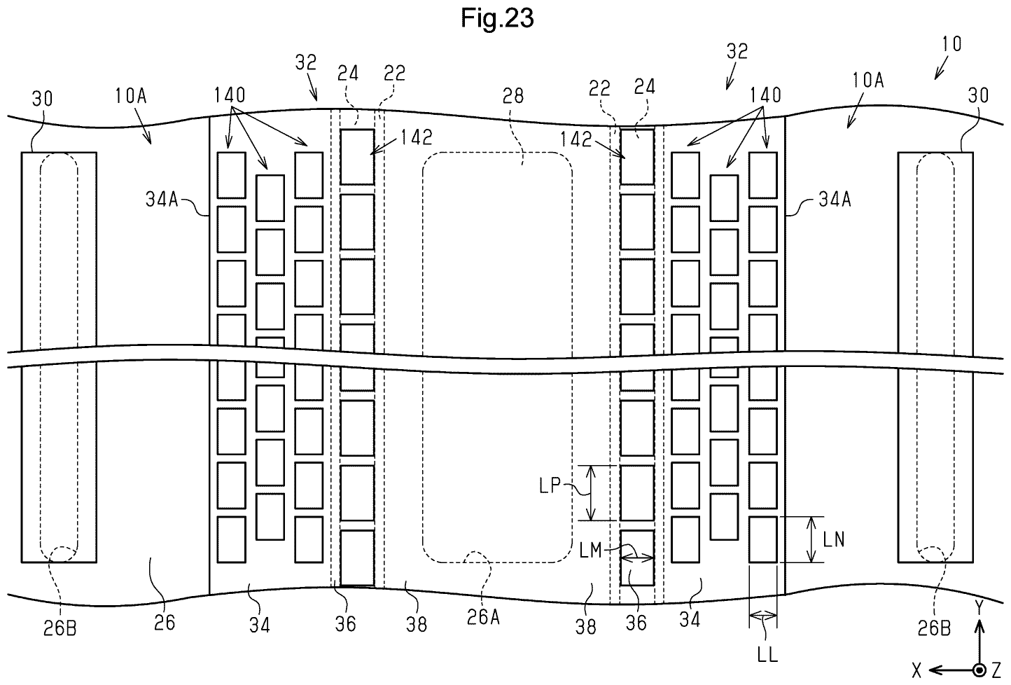

As shown in FIG. 23, the field plate electrode 32 has a first opening 140 and a second opening 142. The first opening 140 is located in the plate extension 34. Thus, at least a portion of the opening is located in the plate extension 34. The second opening 142 is located in the gate opposing portion 36. In other words, the second opening 142 is located at a position that overlaps the gate layer 22 in plan view. Thus, in the example shown in FIG. 23, at least a portion of the opening is located at a position that overlaps the gate layer 22 in plan view. In other words, the opening is located in at least the gate opposing portion 36. Thus, in the example shown in FIG. 23, the opening is located in the plate extension 34 and a position that overlaps the gate layer 22 in plan view.

The first opening 140 includes multiple first openings 140 separated from each other in the X-direction and Y-direction. In the example shown in FIG. 23, the first openings 140 are separated from each other in the Y-direction in each row, and three rows of the first openings 140 are arranged and spaced apart from each other in the X-direction. The layout of the first openings 140 is the same as the layout of the openings 80 shown in FIG. 17. The shape and the size of the first openings 140 are the same as the shape and size of the openings 80.

The second opening 142 includes multiple second openings 142 separated from each other in the Y-direction. In the example shown in FIG. 23, a dimension LM of each second opening in the X-direction is less than a dimension LL of each first opening 140 in the X-direction. A dimension LP of each second opening 142 in the Y-direction is greater than a dimension LN of each first opening 140 in the Y-direction. As described above, in plan view, the proportion of the area of the second openings 142 to the area of the gate opposing portion 36 may be increased. The second openings 142 of the eighth modified example may be applied to the first and second embodiments.

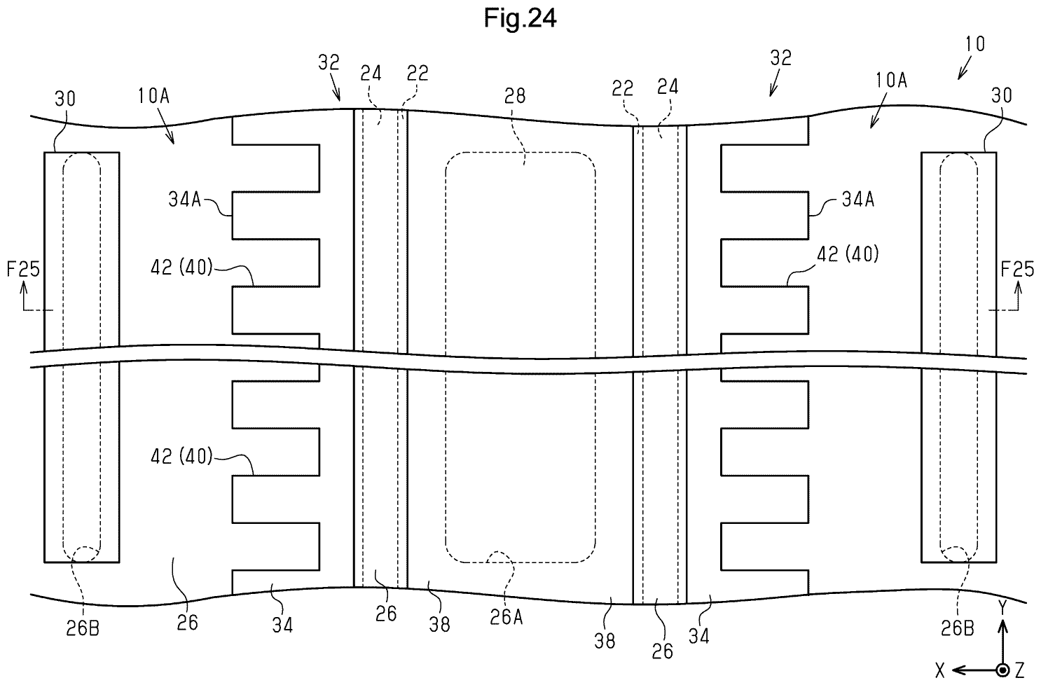

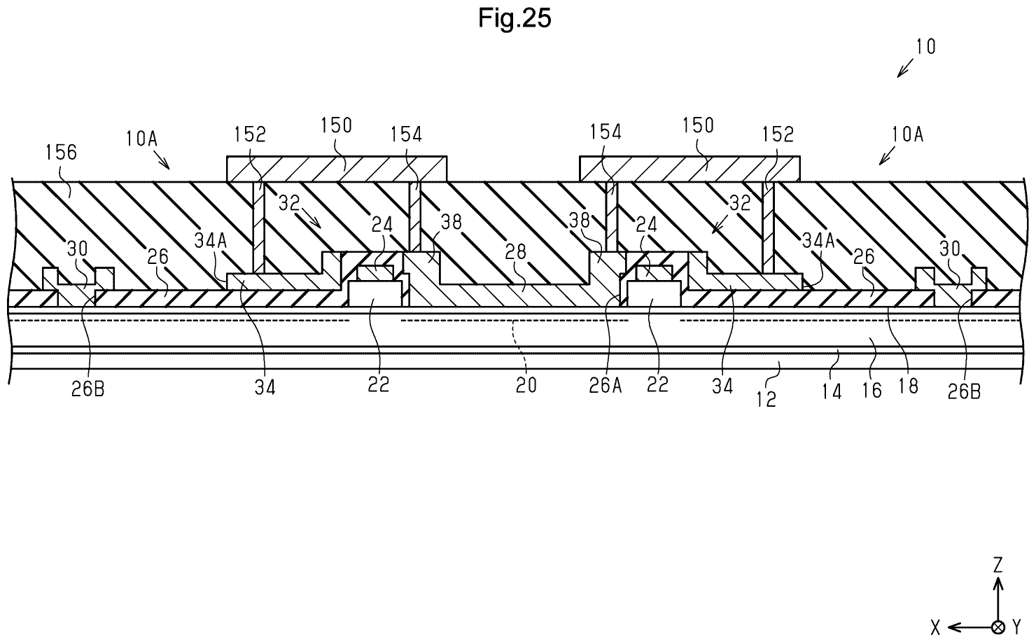

In the embodiments, the gate opposing portion 36 may be omitted from the field plate electrode 32. That is, as shown in FIG. 24, the field plate electrode 32 includes the plate extension 34 and the source connector 38. The plate extension 34 and the source connector 38 are separated from each other in the X-direction. As shown in FIG. 25, the plate extension 34 and the source connector 38 are electrically connected. In an example, the plate extension 34 and the source connector 38 are connected by a wiring layer 150, a first via 152, and a second via 154. The wiring layer 150 and the electron supply layer 18 are separately located at opposite sides of the plate extension 34 and the source connector 38 in the Z-direction. More specifically, the nitride semiconductor device 10 further includes an inter-layer insulation layer 156 formed on the passivation layer 26 and covering the source electrode 28, the drain electrode 30, and the field plate electrode 32. The wiring layer 150 is formed on the inter-layer insulation layer 156. The first via 152 extends through the inter-layer insulation layer 156 in the Z-direction to connect the wiring layer 150 and the plate extension 34. The second via 154 extends through the inter-layer insulation layer 156 in the Z-direction to connect the wiring layer 150 and the source connector 38.

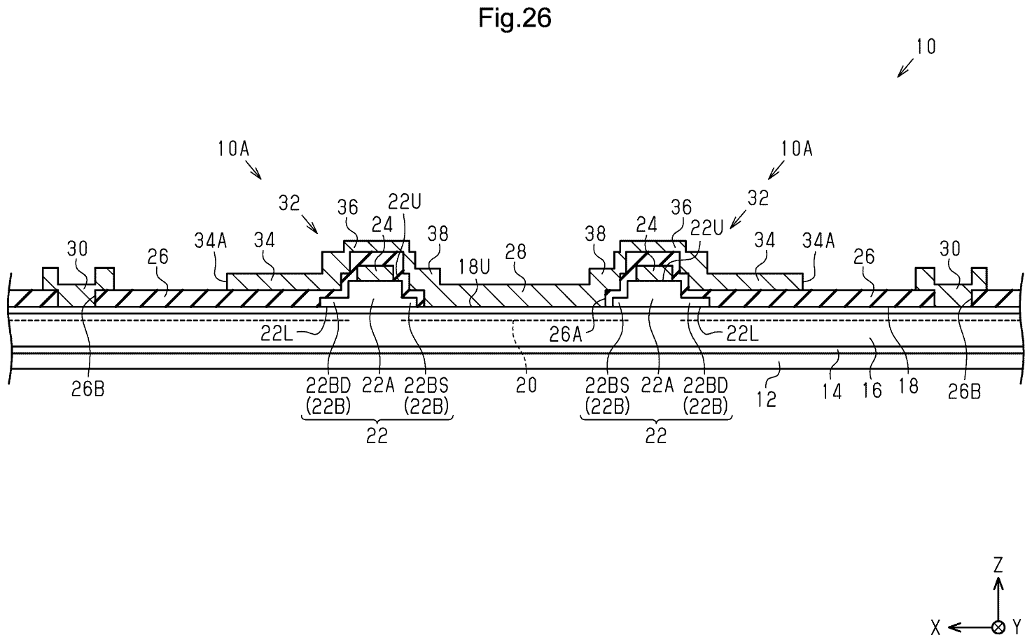

In the embodiment described above, the structure of the gate layer 22 may be changed in any manner. In an example, as shown in FIG. 26, the gate layer 22 includes a ridge 22A and an extension 22B extending from opposite sides of the ridge 22A in opposite directions. The ridge 22A and the extension 22B form a step structure of the gate layer 22.

The ridge 22A corresponds to a relatively thick portion of the gate layer 22. The gate electrode 24 is in contact with the ridge 22A. The ridge 22A may have a rectangular or trapezoidal cross section taken along an XZ plane in FIG. 26. The ridge 22A may have a thickness that is, for example, greater than or equal to 100 nm and less than or equal to 200 nm. The thickness of the ridge 22A is the distance between the upper surface and the lower surface of the ridge 22A (upper surface 22U of the gate layer 22 formed on the gate electrode 24 and lower surface 22L of the gate layer 22 of the electron supply layer 18). The thickness of the ridge 22A (gate layer 22) is determined while taking into consideration various parameters such as the gate breakdown voltage.

The extension 22B includes a source-side extension 22BS and a drain-side extension 22BD. The source-side extension 22BS extends from the ridge 22A toward the first opening 26A in the passivation layer 26. The drain-side extension 22BD extends from the ridge 22A toward the second opening 26B in the passivation layer 26. The source-side extension 22BS and the drain-side extension 22BD may have the same length or different lengths.

The source-side extension 22BS may have a thickness that is, for example, greater than or equal to 5 nm and less than or equal to 30 nm. In a direction extending from the ridge 22A toward the first opening 26A, the source-side extension 22BS may have a length of, for example, 100 nm or longer in the X-direction. The length of the source-side extension 22BS in the X-direction is, for example, greater than or equal to 200 nm and less than or equal to 300 nm. The drain-side extension 22BD may have a thickness that is, for example, greater than or equal to 5 nm and less than or equal to 30 nm. In a direction extending from the ridge 22A toward the second opening 26B, the drain-side extension 22BD may have a length that is, for example, greater than or equal to 200 nm and less than or equal to 600 nm in the X-direction. In an example, the source-side extension 22BS and the drain-side extension 22BD have the same thickness.

The gate layer 22 includes an upper surface 22U and a lower surface 22L. The lower surface 22L of the gate layer 22 is opposed to an upper surface 18U of the electron supply layer 18. The upper surface 22U and the lower surface 22L are located opposite sides of the gate layer 22. The upper surface 22U of the gate layer 22 having a step structure refers to an upper surface of the ridge 22A. The lower surface 22L of the gate layer 22 having the step structure refers to a surface including the lower surface of the ridge 22A, the lower surface of the source-side extension 22BS, and the lower surface of the drain-side extension 22BD.

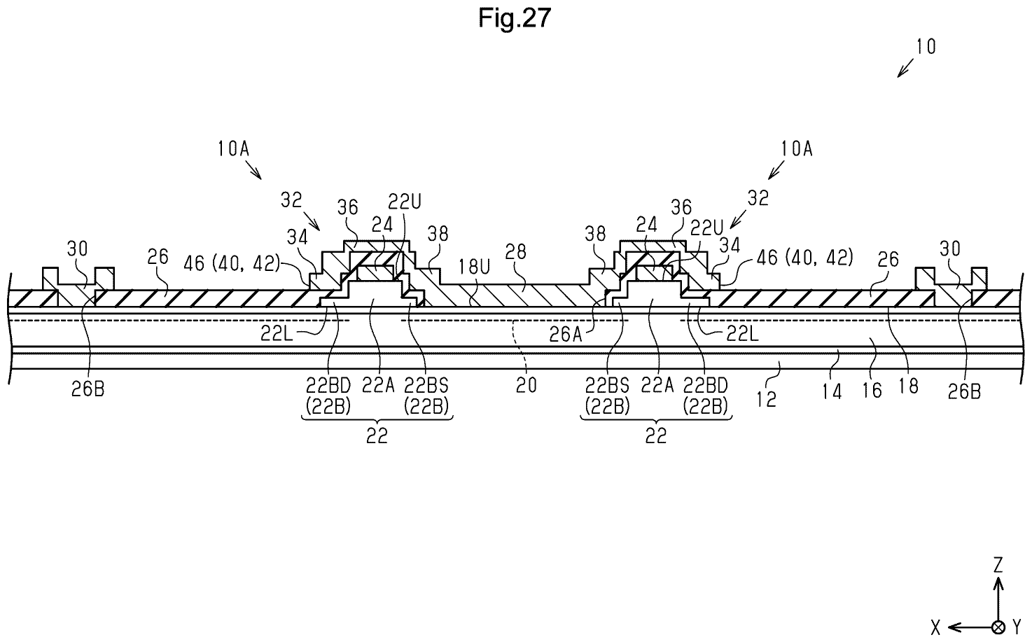

FIG. 27 is a schematic cross-sectional view showing the structure of the nitride semiconductor device 10 taken along an XZ plane differing from that of FIG. 26 in the Y-direction.

As shown in FIG. 27, in the field plate electrode 32, the recess 42, which is the opening 40, is located closer to the plate distal surface 34A (refer to FIG. 26) than the gate layer 22 is. In other words, the bottom surface 46 of the recess 42 is located closer to the plate distal surface 34A than the drain-side extension 22BD of the gate layer 22 is.

One or more of the various examples described in this specification may be combined as long as there is no technical contradiction.

In this specification, “at least one of A and B” should be understood to mean “only A, or only B, or both A and B.”

Terms such as “first,” “second,” and “third” in this disclosure are used to distinguish subjects and not used for ordinal purposes.

In the present disclosure, the term “on” includes the meaning of “above” in addition to the meaning of “on” unless otherwise clearly indicated in the context. Thus, the phrase “component A is formed on component B” is intended to mean that component A may be disposed directly on component B in contact with component B in an embodiment and also that component A may be disposed above component B without contacting component B in another embodiment. Thus, the word “on” will also allow for a structure in which another component is formed between component A and component B.

The Z-direction as referred to in the present disclosure does not necessarily have to be the vertical direction and does not necessarily have to exactly coincide with the vertical direction. Accordingly, in the structures of the present disclosure, “up” and “down” in the z-direction as referred to in this specification is not limited to “up” and “down” in the vertical direction. For example, the X-direction may conform to the vertical direction. The Y-direction may conform to the vertical direction.

### Clauses

Technical concepts that can be understood from each of the above embodiments and modified examples will now be described. It should be noted that, for the purpose of facilitating understanding with no intention to limit, elements described in clauses are given the reference characters of the corresponding elements of the embodiments. The reference signs are used as examples to facilitate understanding, and the elements in each clause are not limited to those elements given with the reference signs.

[Clause 1] A nitride semiconductor device (10), including:
an electron transit layer (16) composed of a nitride semiconductor;
an electron supply layer (18) formed on the electron transit layer (16) and composed of a nitride semiconductor having a band gap that is larger than that of the electron transit layer (16);
a gate layer (22) formed on the electron supply layer (18) and composed of a nitride semiconductor including an acceptor impurity;
a gate electrode (24) formed on the gate layer (22);
a passivation layer (26) covering the electron supply layer (18), the gate layer (22), and the gate electrode (24), the passivation layer (26) including a first opening (26A) and a second opening (26B) separated from each other in a first direction (X-direction), the gate layer (22) being disposed between the first opening (26A) and the second opening (26B);
a source electrode (28) in contact with the electron supply layer (18) through the first opening (26A);
a drain electrode (30) in contact with the electron supply layer (18) through the second opening (26B); and
a filed plate electrode (32) arranged on the passivation layer (26) and electrically connected to the source electrode (28), in which
the filed plate electrode (32) includes a plate extension (34) extending in a region between the gate layer (22) and the drain electrode (30) in plan view and being opposed to the electron supply layer (18) via the passivation layer (26), and
the filed plate electrode (32) has an opening (40) formed in at least one of the plate extension (34) and a position that overlaps the gate layer (22) in plan view.

[Clause 2] The nitride semiconductor device according to clause 1, in which at least a portion of the opening (40) is formed in the plate extension (34).

[Clause 3] The nitride semiconductor device according to clause 2, in which
the plate extension (34) includes a plate distal surface (34A) opposed to the drain electrode (30),
the opening (40) is a recess (42) recessed from the plate distal surface (34A) toward the gate layer (22),
in plan view, a second direction (Y-direction) is orthogonal to the first direction (X-direction), the recess (42) has a width in the second direction (Y-direction) and a depth in the first direction (X-direction) and is open toward the drain electrode (30).

[Clause 4] The nitride semiconductor device according to clause 3, in which a depth (H) of the recess (42) is greater than ½ of a dimension (L) of the plate extension (34) in the first direction (X-direction).

[Clause 5] The nitride semiconductor device according to clause 4, in which
the filed plate electrode (32) includes a gate opposing portion (36) opposed to the gate layer (22) via the passivation layer (26),
the recess (42) extends farther than the plate extension (34) does from the plate distal surface (34A) in the first direction (X-direction) over the plate extension (34) and the gate opposing portion (36).

[Clause 6] The nitride semiconductor device according to any one of clauses 3 to 5, in which the recess (42) includes multiple recesses (42) separated from each other in the second direction (Y-direction).

[Clause 7] The nitride semiconductor device according to clause 6, in which the recesses (42) are separated from each other by a distance (D) that is greater than a width (W) of each recess (42).

[Clause 8] The nitride semiconductor device according to clause 6, in which the recess (42) has a width (W) that is greater than a distance (D) between the recesses (42).

[Clause 9] The nitride semiconductor device according to clause 3, in which the recess (42) has a curved bottom surface (46).

[Clause 10] The nitride semiconductor device according to clause 2, in which
the plate extension (34) includes a plate distal surface (34A) opposed to the drain electrode (30), and
the opening (50) is closed and is located closer to the gate electrode (24) than the plate distal surface (34A) is.

[Clause 11] The nitride semiconductor device according to clause 10, in which, in plan view, the opening (50) is rectangular so that long sides thereof extend in the first direction (X-direction) and short sides thereof extend in a second direction (Y-direction) that is orthogonal to the first direction (X-direction).

[Clause 12] The nitride semiconductor device according to clause 11, in which a dimension (LA) of the opening (50) in the first direction (X-direction) is greater than ½ of a dimension (L) of the plate extension (34) in the first direction (X-direction).

[Clause 13] The nitride semiconductor device according to clause 10, in which, in plan view, the opening (70) is rectangular so that short sides thereof extend in the first direction (X-direction) and long sides thereof extend in a second direction (Y-direction) that is orthogonal to the first direction (X-direction).

[Clause 14] The nitride semiconductor device according to any one of clauses 10 to 12, in which
the filed plate electrode (32) includes a gate opposing portion (36) opposed to the gate layer (22) via the passivation layer (26), and
the opening (60) extends over the plate extension (34) and the gate opposing portion (36).

[Clause 15] The nitride semiconductor device according to clause 1, in which at least a portion of the opening (60) overlaps the gate layer (22) in plan view.

[Clause 16] The nitride semiconductor device according to clause 15, in which
the filed plate electrode (32) includes a gate opposing portion (36) opposed to the gate layer (22) via the passivation layer (26), and
the opening (110) is formed in at least the gate opposing portion (36).

[Clause 17] The nitride semiconductor device according to clause 15 or 16, in which
the gate layer (22) and the drain electrode (30) extend in a second direction (Y-direction) that is orthogonal to the first direction (X-direction) in plan view, and
in a region in which the opening (110) overlaps the gate layer (22) in plan view, the opening (110) is formed in an entire region where the gate layer (22) is opposed to the drain electrode (30) in the first direction (X-direction).

[Clause 18] The nitride semiconductor device according to clause 1 or 2, in which the opening (130) is circular or elliptical.

[Clause 19] The nitride semiconductor device according to any one of clauses 3 to 9, in which the gate layer (22) includes
a ridge (22A) in contact with the electron supply layer (18),
a source-side extension (22BS) in contact with the electron supply layer (18), the source-side extension (22BS) extending from the ridge (22A) toward the source electrode (28) in the first direction (X-direction) and being smaller in thickness than the ridge (22A), and
a drain-side extension (22BD) in contact with the electron supply layer (18), the drain-side extension (22BD) extending from the ridge (22A) toward the drain electrode (30) in the first direction (X-direction) and being smaller in thickness than the ridge (22A).

[Clause 20] The nitride semiconductor device according to clause 19, in which the recess (42) has a bottom surface (46) located closer to the drain electrode (30) in the first direction (X-direction) than the drain-side extension (22BD) is.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
an electron transit layer composed of a nitride semiconductor;
an electron supply layer formed on the electron transit layer and composed of a nitride semiconductor having a band gap that is larger than that of the electron transit layer;
a gate layer formed on the electron supply layer and composed of a nitride semiconductor including an acceptor impurity;
a gate electrode formed on the gate layer;
a passivation layer covering the electron supply layer, the gate layer, and the gate electrode, the passivation layer including a first opening and a second opening separated from each other in a first direction, the gate layer being disposed between the first opening and the second opening;
a source electrode in contact with the electron supply layer through the first opening;
a drain electrode in contact with the electron supply layer through the second opening; and
a filed plate electrode arranged on the passivation layer and electrically connected to the source electrode, wherein
the filed plate electrode includes a plate extension extending in a region between the gate layer and the drain electrode in plan view and being opposed to the electron supply layer via the passivation layer, and
the filed plate electrode has an opening formed in at least one of the plate extension and a position that overlaps the gate layer in plan view.

2. The nitride semiconductor device according to claim 1, wherein at least a portion of the opening is formed in the plate extension.

3. The nitride semiconductor device according to claim 2, wherein
the plate extension includes a plate distal surface opposed to the drain electrode,
the opening is a recess recessed from the plate distal surface toward the gate layer,
in plan view, a second direction is orthogonal to the first direction, the recess has a width in the second direction and a depth in the first direction and is open toward the drain electrode.

4. The nitride semiconductor device according to claim 3, wherein a depth of the recess is greater than ½ of a dimension of the plate extension in the first direction.

5. The nitride semiconductor device according to claim 4, wherein
the filed plate electrode includes a gate opposing portion opposed to the gate layer via the passivation layer,
the recess extends farther than the plate extension does from the plate distal surface in the first direction over the plate extension and the gate opposing portion.

6. The nitride semiconductor device according to claim 3, wherein the recess includes multiple recesses separated from each other in the second direction.

7. The nitride semiconductor device according to claim 6, wherein the recesses are separated from each other by a distance that is greater than a width of each recess.

8. The nitride semiconductor device according to claim 6, wherein the recess has a width that is greater than a distance between the recesses.

9. The nitride semiconductor device according to claim 3, wherein the recess has a curved bottom surface.

10. The nitride semiconductor device according to claim 2, wherein
the plate extension includes a plate distal surface opposed to the drain electrode, and
the opening is closed and is located closer to the gate electrode than the plate distal surface is.

11. The nitride semiconductor device according to claim 10, wherein, in plan view, the opening is rectangular so that long sides thereof extend in the first direction and short sides thereof extend in a second direction that is orthogonal to the first direction.

12. The nitride semiconductor device according to claim 11, wherein a dimension of the opening in the first direction is greater than ½ of a dimension of the plate extension in the first direction.

13. The nitride semiconductor device according to claim 10, wherein, in plan view, the opening is rectangular so that short sides thereof extend in the first direction and long sides thereof extend in a second direction that is orthogonal to the first direction.

14. The nitride semiconductor device according to claim 10, wherein
the filed plate electrode includes a gate opposing portion opposed to the gate layer via the passivation layer, and
the opening extends over the plate extension and the gate opposing portion.

15. The nitride semiconductor device according to claim 1, wherein at least a portion of the opening overlaps the gate layer in plan view.

16. The nitride semiconductor device according to claim 15, wherein
the filed plate electrode includes a gate opposing portion opposed to the gate layer via the passivation layer, and
the opening is formed in at least the gate opposing portion.

17. The nitride semiconductor device according to claim 15, wherein
the gate layer and the drain electrode extend in a second direction that is orthogonal to the first direction in plan view, and
in a region in which the opening overlaps the gate layer in plan view, the opening is formed in an entire region where the gate layer is opposed to the drain electrode in the first direction.

18. The nitride semiconductor device according to claim 1, wherein the opening is circular or elliptical.
